(19) United States
(12) Patent Application Publication
(10) Pub. No.: US 2023/0157021 A1
(43) Pub. Date: May 18, 2023

(54) 3D FLUSH MEMORY HAVING IMPROVED STRUCTURE

(71) Applicants: IUCF-HYU (INDUSTRY-UNIVERSITY COOPERATION FOUNDATION HANYANG UNIVERSITY), Seoul (KR); PeDiSem Co., Ltd., Seoul (KR)

(72) Inventor: Yun Heub SONG, Seoul (KR)

(73) Assignees: IUCF-HYU (INDUSTRY-UNIVERSITY COOPERATION FOUNDATION HANYANG UNIVERSITY), Seoul (KR); PeDiSem Co., Ltd., Seoul (KR)

(21) Appl. No.: 17/923,104

(22) PCT Filed: May 4, 2021
(86) PCT No.: PCT/KR2021/005596

§ 371 Date: Nov. 3, 2022

(30) Foreign Application Priority Data
May 4, 2020 (KR) 10-2020-0053104
May 4, 2020 (KR) 10-2020-0053105
Jun. 5, 2020 (KR) 10-2020-0068007

(51) Int. Cl. H10B 43/27

(52) U.S. Cl. CPC H10B 43/27

(57) ABSTRACT

Disclosed is a three 3D flash memory having an improved structure and a method for manufacturing the same.

### TECHNICAL FIELD

The following embodiments relate to a 3D flash memory and a method for manufacturing the same, and more particularly, to a 3D flash memory having an improved structure and a method for manufacturing the same.

### BACKGROUND ART

The flash memory device, which is an electrically erasable programmable read only memory (EEPROM), may be commonly used, for example, for a computer, a digital camera, an MP3 player, a game system, and a memory stick. The flash memory device electrically controls the input and output of data through Fowler-Nordheim tunneling or hot electron injection.

In detail, referring to FIG. 1 showing an array of a conventional 3D flash memory, the array of the 3D flash memory may include a common source line CSL, a bit line BL, and a plurality of cell strings CSTR interposed between the common source line CSL and the bit line BL.

Bit lines are arranged two-dimensionally, and the plurality of cell strings CSTR are connected in parallel with each of the bit lines. The cell strings CSTR may be connected in common with the common source line CSL. In other words, the plurality of cell strings CSTR may be interposed between a plurality of bit lines and one common source line CSL. In this case, a plurality of common source lines CSL may be provided, and may be two-dimensionally arranged. In this case, the same voltage may be electrically applied to the plurality of common source lines CSL, or each of the plurality of common source lines CSL may be electrically controlled.

Each of the cell strings CSTR may include a ground selection transistor GST connected with the common source line CSL, a string selection transistor SST connected with the bit line BL, and a plurality of memory cell transistors MCT interposed between the ground selection transistor GST and the string selection transistor SST. In addition, the ground selection transistor GST, the string selection transistor SST, and the memory cell transistors MCT may be connected to each other in series.

The common source line CSL may be connected in common sources of the ground selection transistors GST. In addition, a ground selection line GSL, a plurality of word lines WL0 to WL3, and a plurality of string selection lines SSL, which are interposed between the common source line CSL and the bit line BL, may be respectively used as electrode layers of the ground selection transistors GST, the memory cell transistors MCT, and the string selection transistors SST. In addition, each of the memory cell transistors MCT includes a memory element. Hereinafter, the string selection line SSL may be expressed as an upper selection line USL, and the ground selection line GSL may be expressed as a lower selection line LSL.

Meanwhile, a conventional 3D flash memory may increase the degree of integration by vertically stacking cells to satisfy the demands for excellent performance and a low price of a consumer.

For example, referring to FIG. 2 showing a structure of a conventional 3D flash memory, the conventional 3D flash memory is manufactured by arranging electrode structures 215 in which interlayer insulating layers 211 and horizontal structures 250 are alternately and repeatedly formed on a substrate 200. The interlayer insulating layers 211 and the horizontal structures 250 may extend in a first direction. The interlayer insulating layers 211 may be, for example, a silicon oxide layer, and a lowest interlayer insulating layer 211a of the interlayer insulating layers 211 may be thinner than the remaining interlayer insulating layers 211. Each of the horizontal structures 250 may include a first blocking insulating layer 242, a second blocking insulating layer 243, and an electrode layer 245. A plurality of electrode structures 215 may be provided, and may be arranged to face each other in a second direction crossing the first direction. The first direction and the second direction may correspond to an x-axis and a y-axis of FIG. 2, respectively. Trenches 240 may extend in the first direction such that the plurality of electrode structures 215 are spaced from each other. Impurity regions heavily doped may be formed in the substrate 200 exposed by the trenches 240 such that the common source line CSL is disposed. Although not illustrated, separation insulating layers may be further provided to be filled in the tranches 240.

Vertical structures 230 may be disposed to pass through the electrode structures 215. For example, when viewed from a plan view, the vertical structures 230 may be aligned in the first and second directions to be disposed in a matrix form. For another example, the vertical structures 230 may be aligned in the second direction to be arranged while forming a zigzag form in the first direction. Each of the vertical structures 230 may include a protective layer 224, a charge storage layer 225, a tunnel insulating layer 226, and a channel layer 227. For example, the channel layer 227 may be disposed in the form of a hallow tube. In this case, a buried layer may be further disposed to fill the inside of the channel layer 227. A drain region D may be disposed on the channel layer 227, and a conductive pattern 229 may be formed on the drain region D to be connected with a bit line BL. The bit line BL may extend in a direction, for example, the second direction crossing the horizontal electrodes 250. For example, the vertical structures 230 aligned in the second direction may be connected with one bit line BL.

The first and second blocking insulating layers 242 and 243, which are included in the horizontal structure 250, and the charge storage layer 225 and the tunnel insulating layer 226, which are included in the vertical structure 230, may be defined as an oxide-nitride-oxide (ONO) layer serving as an information storage element of the 3D flash memory. In other words, a portion of the information storage element may be included in the vertical structure 230, and the remaining portion thereof may be included in the horizontal structure 250. For example, the charge storage layer 225 and the tunnel insulating layer 226 of the information storage element may be included in the horizontal structure 230, and the first and second blocking insulating layers 242 and 243 may be included in the horizontal structure 250, but the present disclosure is not limited thereto.

Epitaxial patterns 222 may be disposed between the substrate 200 and the vertical structures 230. The epitaxial patterns 222 connect the substrate 200 and the vertical structures 230. The epitaxial patterns 222 may make contact with the horizontal structures 250 in at least one layer. That is, the epitaxial patterns 222 may be disposed to make contact with the lowest horizontal structure 250a. According to another embodiment, the epitaxial patterns 222 may be disposed to make contact with the horizontal structures 250 in a plurality of layers, for example, two layers. Meanwhile, when the epitaxial patterns 222 are disposed to make contact with the lowest horizontal structure 250a, the lowest horizontal structure 250a may be disposed to be thicker than the remaining horizontal structures 250. The lowest horizontal structure 250a making contact with the epitaxial patterns 222 may correspond to the ground selection line GSL of the array in the 3D flash memory described with reference to FIG. 1, and the remaining horizontal structures 250 make contact with the vertical structures 230 may correspond to the plurality of word lines WL0 to WL3, respectively.

Each of the epitaxial patterns 222 includes a sidewall 222a which is recessed. Accordingly, the lowest horizontal structure 250a making contact with the epitaxial patterns 222 is disposed along a profile of the sidewall 222A which is recessed. In other words, the lowest horizontal structure 250a may be disposed to be convex inwardly along the recessed side wall 222a of the epitaxial pattern 222.

As the conventional 3D flash memory having such a structure is increased in the number of vertically stacked steps, the length of the channel layer 227 is increased, thereby reducing a cell current and deteriorating a cell characteristic.

According to following embodiments the cell current, which is decreased as the length of the channel layer is increased, may be increased, and the degradation of the cell characteristic resulting from the reduction in the cell current is prevented in the 3D flash memory.

In addition, according to the conventional 3D flash memory, as the channel layer 227 is formed of polysilicon, a great leakage current may be caused. Accordingly, to improve the leakage current characteristic, a technology of forming the channel layer 227 by using an oxide semiconductor material, such as an IGZO material, showing an excellent current characteristic is suggested.

However, the oxide semiconductor material, such as the IGZO material, is significantly degraded in hole mobility, such that the memory operation based on hole injection may not be supported.

Therefore, the following embodiments are to suggest a technology of improving the leakage current characteristic while supporting the memory operation based on the hole injection.

Meanwhile, referring to FIG. 3 which is a cross-sectional view illustrating a plug line of the 3D flash memory, in a conventional 3D flash memory, a plug line 321 to connect a bit line 310 to a string 320 is not manufactured with a thinner thickness (e.g., the thickness in the range of 10 nm to 50 nm) due to the limitation in the manufacturing process. Accordingly, to selectively control the string 320, a strapping line 330 and an additional plug line 331 to connect the strapping line 330 to the bit line 310 are provided. Accordingly, the conventional 3D flash memory has the structure in which the bit line 310 is connected to the string 320 and the strapping line 330 through two plug lines 321 and 331, thereby increasing the costs for manufacturing lines.

Accordingly, there need to suggest a bit line connection structure for reducing the costs for manufacturing the line.

### DETAILED DESCRIPTION OF THE INVENTION

### Techinical Problem

Embodiments suggest a 3D flash memory in a structure of employing at least two intermediate lines disposed at an intermediate point in the direction in which the at least one string extends, and fixedly used as a source electrode or a drain electrode for the at least one string, and a method for manufacturing the same.

In this case, embodiments suggest a 3D flash memory, capable of reducing a circuit complexity, in which a source electrode-related line or a drain electrode-related line are connected, and a control complexity, in which at least two intermediates lines are controlled, when forming the at least two intermediate lines, and a method for manufacturing the same.

In addition, embodiments suggest a 3D flash memory in which drain junctions are positioned at the same positions, which are symmetrical to each other, on at least one upper string and at least one lower string which are obtained by dividing at least one string into two parts by at least two intermediate lines, and a method for operating the same.

Embodiments suggest a 3D flash memory capable of improving a leakage current characteristic and supporting a memory operation based on a hole injection based.

In more detail, embodiments suggest a 3D flash memory including a channel layer having a first region including single crystalline silicon or polysilicon and a second region formed at an upper portion or a lower portion of the first region using an oxide semiconductor material, such that an excellent characteristic against a leakage current of the oxide semiconductor material is shown through the second region, and the memory operation based on the hole injection is supported through the first region.

In this case, embodiments suggest a 3D flash memory for supporting a memory operation based on hole injection through any one of a scheme of injecting a hole from the bulk of a substrate through a first region or a scheme of injecting, from a selection line, a hole due to Gate Induced Drain Leakage (GIDL) through an N-type junction formed in a contact interface between the first region and the second region.

Embodiments suggest a 3D flash memory having a cost effective bit-line connection structure to reduce manufacturing costs for a line in the 3D flash memory and a method for manufacturing the same.

In more detail, embodiments suggest a 3D flash memory having a structure in which a bit line is directly connected to a string through one plug line, and a method for operating the same.

### Technical Solution

According to an embodiment, a 3D flash memory includes a substrate, at least one string extending in one direction on the substrate, and at least two intermediate lines disposed at an intermediate point in the direction in which the at least one string extends, in which each of the at least two intermediate lines are fixedly used as a source electrode or a drain electrode for the at least one string.

According to an aspect, the at least two intermediate lines may include at least one intermediate source line used as a source electrode for the at least one string, and at least one intermediate drain line used as a drain electrode for the at least one string.

According to another aspect, each of the at least one intermediate source line and the at least one intermediate drain line may be provided to be separated from each other in a single layer.

According to still another aspect, each of the at least one intermediate source line and the at least one intermediate drain line may be provided in mutually different layers.

According to still another aspect, the at least one intermediate source line and the at least one intermediate drain line may be connected to mutually different strings, respectively, of at least one upper string and at least one lower string which are obtained by dividing the at least one string into two parts by the at least one intermediate source line and the at least one intermediate drain line.

According to an embodiment, a 3D flash memory includes a string extending in one direction on a substrate, in which the string includes a channel layer extending in the one direction and a charge storage layer extending in the one direction while surrounding the channel layer; at least one selection line connected to an upper end or a lower end of the string in a vertical direction; and a plurality of word lines positioned at an upper portion or a lower portion of the at least one selection line and connected to the string in the vertical direction, in which the channel layer may include a first region corresponding to the plurality of word lines and a second region corresponding to the at least one selection line, and the first region and the second region may include mutually different materials.

According to an aspect, the first region includes single crystalline silicon or polysilicon, and the second region includes an oxide semiconductor material.

According to another aspect, the second region may be used to block a leakage current for the at least one selection line, and improve a characteristic of a transistor of the at least one selection line.

According to still another aspect, the second region may further include an N-type junction formed on a contact interface with the first region.

According to still another aspect, the N-type junction may be used to reduce a contact resistance between the first region and the second region.

According to still another aspect, the at least one selection line may be adjacent to one of the upper end or the lower end of the string in the vertical direction and includes a plurality of selection lines, and the second region may be used to block a leakage current for an upper selection line of two selection lines, improve a characteristic of a transistor of the at least one selection line, and inject a hole into the first region through the N-type junction in relation to a lower selection line of the two selection lines.

According to an embodiment, a 3D flash memory includes a substrate; at least one string extending in one direction on the substrate; at least one plug line formed on the at least one string; and at least one bit line connected to the at least one string through the at least one plug line, in which the at least one bit line is directly connected to the at least one string through only the at least one plug line without passing through a component other than the at least one plug line.

According to an aspect, a contact metal pad may be formed on the at least one string.

According to another aspect, the contact metal pad may include a metal material applied on an entire region of an upper portion of the at least one string to reduce a contact resistance with the at least one plug line.

According to still another aspect, a position for forming the at least one plug line on the at least one string may be determined based on a position in which at least one different plug line on at least one different string positioned in the same column or the same row as a position of the at least one string is formed on the at least one different string.

### Advantageous Effects of the Invention

Embodiments may suggest a 3D flash memory in a structure of employing at least two intermediate lines disposed at an intermediate point in the direction in which the at least one string extends, and fixedly used as a source electrode or a drain electrode for the at least one string, and a method for manufacturing the same.

Accordingly, according to embodiments, the cell current of the conventional 3D flash memory may be reduced, and the deterioration of the cell characteristic may be overcome.

In this case, embodiments may suggest a 3D flash memory, capable of reducing a circuit complexity, in which a source electrode-related line or a drain electrode-related line are connected, and a control complexity, in which at least two intermediates lines are controlled, when forming the at least two intermediate lines, and a method for manufacturing the same.

In addition, embodiments may suggest a 3D flash memory in which drain junctions are positioned at the same positions, which are symmetrical to each other, on at least one upper string and at least one lower string which are obtained by dividing at least one string into two parts by at least two intermediate lines, and a method for operating the same.

Accordingly, embodiments may suggest a technology of preventing manufacturing costs from being increased when asymmetrical drain junctions are formed on at least one upper string and at least lower string.

Embodiments may suggest a 3D flash memory capable of improving a leakage current characteristic and supporting a memory operation based on a hole injection based.

In more detail, embodiments may suggest a 3D flash memory including a channel layer having a first region including single crystalline silicon or polysilicon and a second region formed at an upper portion or a lower portion of the first region using an oxide semiconductor material, such that an excellent characteristic against a leakage current of the oxide semiconductor material is shown through the second region, and the memory operation based on the hole injection is supported through the first region.

In this case, embodiments may suggest a 3D flash memory for supporting a memory operation based on hole injection through any one of a scheme of injecting a hole from the bulk of a substrate through a first region or a scheme of injecting, from a selection line, a hole due to Gate Induced Drain Leakage (GIDL) through an N-type junction formed in a contact interface between the first region and the second region.

Embodiments may suggest a 3D flash memory having a cost effective bit-line connection structure to reduce manufacturing costs for a line in the 3D flash memory and a method for manufacturing the same.

In more detail, embodiments may suggest a 3D flash memory having a structure in which a bit line is directly connected to a string through one plug line, and a method for operating the same.

### DESCRIPTION OF THE DRAWINGS

FIG. 1 is a circuit diagram illustrating an array of a conventional 3D flash memory;

FIG. 2 is a perspective view illustrating a structure of a conventional 3D flash memory;

FIG. 3 is a cross-sectional view illustrating a plug line of a conventional 3D flash memory;

FIG. 4 is an x-z cross-sectional view illustrating a 3D flash memory according to an embodiment;

FIG. 5 is an x-y cross-sectional view illustrating a 3D flash memory according to an embodiment;

FIG. 6 is an x-z cross-sectional view illustrating a 3D flash memory according to another embodiment;

FIG. 7 is an x-y cross-sectional view illustrating a 3D flash memory according to another embodiment;

FIG. 8 is a flowchart illustrating a method for manufacturing a 3D flash memory according to an embodiment;

FIGS. 9A to 9F are x-z cross-sectionals view illustrating a method for manufacturing a 3D flash memory illustrated in FIGS. 4 to 5;

FIGS. 10A to 10F are x-z cross-sectional views illustrating a method of manufacturing a 3D flash memory illustrated in FIGS. 6 to 7;

FIG. 11 is a y-z cross-sectional view illustrating a 3D flash memory according to an embodiment;

FIG. 12 is a flowchart illustrating a method for manufacturing a 3D flash memory according to an embodiment;

FIGS. 13A to 13F are y-z cross-sectional views illustrating a method of manufacturing a 3D flash memory according to an embodiment;

FIG. 14 is a y-z cross-sectional view illustrating a 3D flash memory according to an embodiment;

FIG. 15 is an x-z cross-sectional view illustrating a 3D flash memory according to another embodiment;

FIG. 16 is an x-y cross-sectional view illustrating a 3D flash memory according to another embodiment;

FIG. 17 is a flowchart illustrating a method for manufacturing a 3D flash memory according to an embodiment;

FIGS. 18A to 18F are a x-z cross-sectional views illustrating a method for manufacturing a 3D flash memory according to an embodiment;

FIG. 19 is an x-z cross-sectional view illustrating a 3D flash memory according to another embodiment;

FIG. 20 is an x-y cross-sectional view illustrating a 3D flash memory according to another embodiment;

FIG. 21 is a flowchart illustrating a method for manufacturing a 3D flash memory according to another embodiment; and

FIGS. 22A to 22E are x-y sectional views illustrating a method for manufacturing a 3D flash memory according to another embodiment.

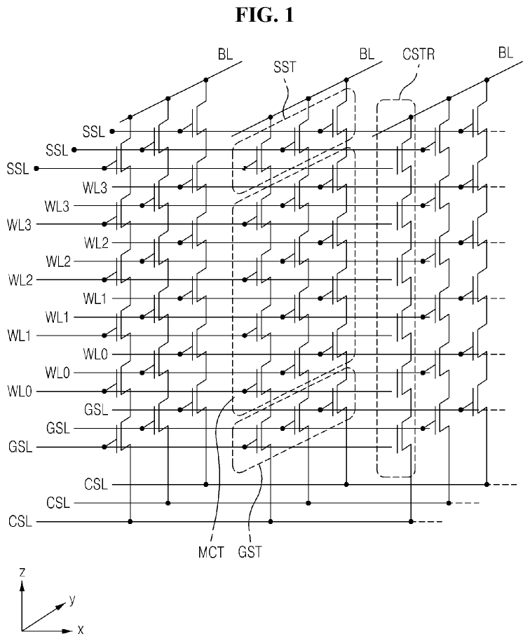

### BEST MODE

Hereinafter, embodiments will be described in detail with reference to the accompanying drawings. However, the present disclosure is not limited or restricted by the embodiments. Further, the same reference signs/numerals in the drawings denote the same members.

Furthermore, the terminology used herein are used to properly express the embodiments of the present disclosure, and may be changed according to the intentions of the user or the manager or the custom in the field to which the present disclosure pertains. Accordingly, definition of the terminology should be made according to the overall disclosure set forth herein.

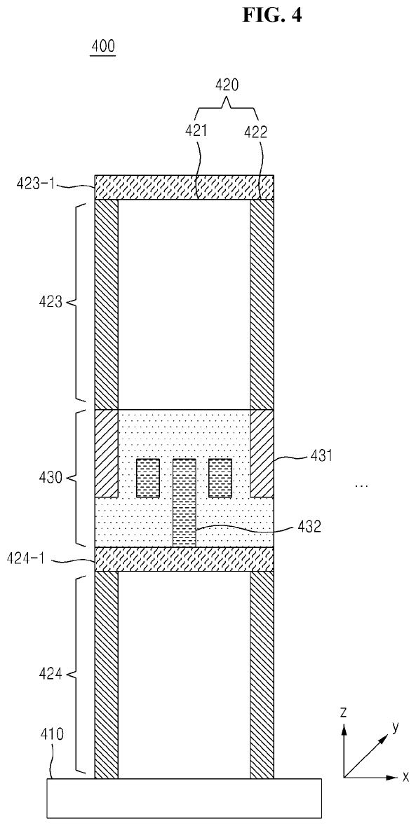

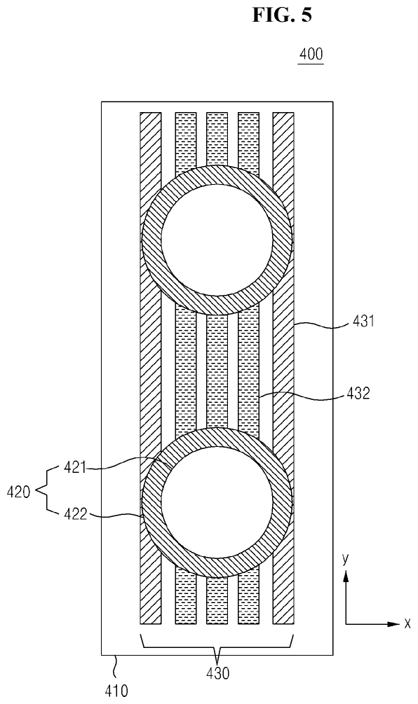

FIG. 4 is an x-z cross-sectional view illustrating a 3D flash memory according to an embodiment, and FIG. 5 is an x-y cross-sectional view illustrating a 3D flash memory according to an embodiment.

Referring to FIGS. 4 to 5, a 3D flash memory 400 according to an embodiment includes a substrate 410, at least one string 420 extending in one direction on the substrate 410, and at least two intermediate lines 430 disposed at an intermediate point in a direction in which the at least one string 420 extends.

Hereinafter, the 3D flash memory 420 may further include a plurality of word lines (not illustrated), a plurality of insulating layers (not illustrated) interposed between the plurality of word lines, an upper wiring layer (not illustrated) disposed on at least one string 420, and a lower wiring layer (not illustrated) disposed under the at least one string 420, while essentially including the substrate 410, the at least one string 420, and the at least two intermediate lines 430.

In this case, the plurality of word lines are formed of conductive materials, such as tungsten (W), titanium (Ti), tantallium (Ta), copper (Cu), or gold (Au) to apply a voltage to each relevant one of the memory cells, thereby performing a program operation and an erase operation. The upper wiring layer and the lower wiring layer may be used as a bit line and a source line, respectively, while being connected to the String Selection Line (SSL) and the Ground Selection Line (GSL) of at least one string 420. Similarly, each of the upper wiring layer and the lower wiring layer may be formed of a conductive material such as tungsten (W), titanium (Ti), tantallium (Ta), copper (Cu), or gold (Au).

The at least one string 420 includes at least one channel layer 421 extending in one direction and at least one charge storage layer 422 formed to surround the at least one channel layer 421. The at least one charge storage layer 422, which is a component to store charges resulting from a voltage applied through the plurality of word lines (not illustrated) serves as a data storage in the 3D flash memory 400, and may be formed in a structure of ONO (Oxide-Nitride-Oxide). The at least one channel layer 421 may be formed of single crystalline silicon or polysilicon and may be disposed in the form of an internal hollow tube. In this case, a buried layer (not illustrated) may be further disposed to fill the inside of the at least one channel layer 421. Accordingly, at least one string 420 may constitute memory cells corresponding to the plurality of word lines connected in a vertical direction.

The at least two intermediate lines 430 may be formed of at least one of a metal conductive material, such as tungsten (W), titanium (Ti), tantallium (Ta), copper (Cu), or gold (Au), such that the at least two intermediate lines 430 may be fixedly used for the at least one string 420 while serving as mutually different electrodes of the source electrode or the drain electrode, respectively. For example, the at least two intermediate lines 430 may be formed to extend in the y-direction.

In this case, the wording “the at least two intermediate lines 430 may be fixedly used for the at least one string 420 while serving as mutually different electrodes of the source electrode or the drain electrode, respectively” refers to that any one intermediate line 430 of the at least two intermediate lines 430 is fixedly used for any one (e.g., an upper string 423) of at least one upper string 423 or at least one lower string 424, which is obtained by dividing the at least one string 420 into two parts by at least two intermediate lines 430, while serving as the source electrode, and a remaining one intermediate line 430 is fixedly used for a remaining one string (e.g., the at least one lower string 424) of the at least one upper string 423 or the at least one lower string 424 while serving as the drain electrode.

In other words, the at least two intermediate lines 430 may include at least one intermediate source line 431 serving as a source electrode for the at least one string 420, and at least one intermediate drain line 432 serving as a drain electrode for the at least one string 420. Hereinafter, although the at least two intermediate lines 430 include two intermediate source lines 431 and three intermediate drain lines 432, the number of intermediate lines are not limited thereto.

Since the at least two intermediate lines 430 are formed on a single layer as illustrated in the drawings, the at least two intermediate lines 430 may correspond to one intermediate wiring layer. However, the at least two intermediate lines 430 may be formed separately from each other in a single layer, and thus may be used independently For example, at least one intermediate source line 431 and at least one intermediate drain line 432 may be separated from each other by being disposed to be spaced apart from each other by a specific distance from left to right in a single layer. Hereinafter, the wording “the at least two intermediate lines 430 may be formed separately from each other in a single layer” may include the concept that at least a portion of the at least one intermediate drain line 432 and at least a portion of at least one intermediate source line 431 are formed in the single layer (positioned on the same plane).

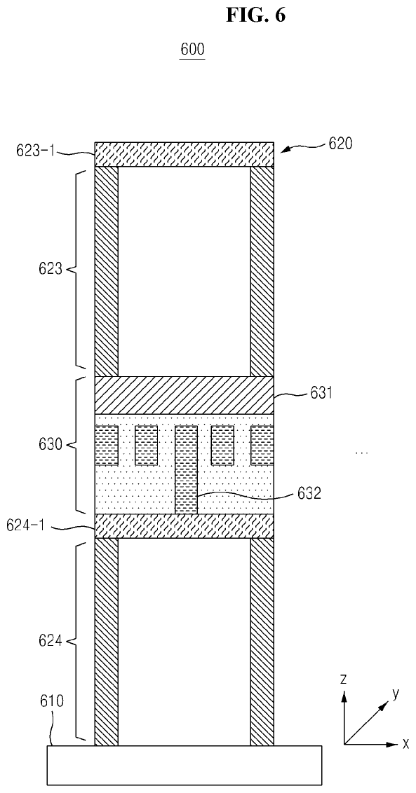

However, the present disclosure is not limited thereto. For example, at least two intermediate lines 430 may be formed to be separated from each other in a vertical direction in one intermediate wiring layer. Hereinafter, the details thereof will be described with reference to FIGS. 5 to 6.

As described above, since at least two intermediate lines 430 should be used as mutually different electrodes for at least one upper string 423 or at least one lower string 424, such that the at least two intermediate lines 430 may be connected to mutually different strings of at least one upper string 423 or at least one lower string 424. For example, at least one intermediate source line 431 of the at least two intermediate lines 430 is connected to the at least one upper string 423 while fixedly serving as a source electrode. At least one intermediate drain line 432 may be connected to at least one lower string 424 while fixedly serving as a drain electrode.

The spacing between the at least two intermediate lines 430 may be set to be in the range of 10 nm and 50 nm, based on the cross-sectional size of the at least one string 420, the number of at least two intermediate lines 430, and the thickness of each of the at least two intermediate lines 430. For example, when considering that the cross-section diameter of at least one string 420 is 120 nm and the thickness of each of the two intermediate lines 430 is 10 nm, the spacing between the at least two intermediate lines 430 may be set to be in the range of 10 nm and 50 nm, such that at least two intermediate lines 430 may be disposed within the cross-section of at least one string 420.

In addition, the at least two intermediate lines 430 are formed simultaneously with the metal of the transistor (not illustrated) included in the substrate 410 (the metal of the transistor and the at least two intermediate lines 430 are formed at the same time through the same process), thereby simplifying the manufacturing process.

In addition, at least two intermediate lines 430 may be shared and used by a plurality of strings when the 3D flash memory 400 includes a plurality of strings including at least one string 420. For example, at least one outer intermediate source line 431 of the at least two intermediate source lines 430 may be shared and used by strings adjacent to each other in a horizontal direction.

As described above, as the at least two intermediate lines 430 are included, the 3D flash memory 400 fixedly employs the different intermediate lines 431 and 432 as any one electrode of the intermediate source electrode or the intermediate drain, thereby reducing a circuit complexity in which a source electrode-related line or a drain electrode-related line are connected, and a control complexity in which at least two intermediates lines are controlled, in the structure including the intermediate wiring layer.

In addition, as described above, as two intermediate lines 430 are included, the 3D flash memory 400 may form drain doping 423-1 and 424-1 at same positions, which are symmetrical to each other, of at least one lower string 424 and at least one upper string 423, which are obtained by dividing at least one string 420 by the intermediate wiring layer, in the structure including the intermediate wiring layer. For example, the drain doping 423-1 and 424-1 may be formed at the same upper positions in the at least one lower string 424 and the at least one upper string 423. Accordingly, the manufacturing costs may be prevented from being increased as asymmetric drain junctions are formed in the structure including the intermediate wiring layer. For reference, the drain doping 423-1 and 424-1 are not illustrated in FIG. 4 for the illustrative purpose.

In addition, according to the 3D flash memory 400, the at least two intermediate lines 430 are formed in the shape of a step or an inverse step, together with the upper wiring layer disposed on the at least one string 420 and the lower wiring layer disposed under the at least one string 420, thereby simplifying a memory wiring process and improving the degree of integration. In addition, the 3D flash memory 400 may be configured such that the upper wiring layer, at least two intermediate lines 430, and the lower wiring layer have the shape of steps having lengths sequentially increasingly extending in a direction perpendicular to an extension direction of the at least one string 420, and the shape of inverse steps having lengths sequentially decreasingly extending in a direction perpendicular to an extension direction of the at least one string 420. In other words, the upper wiring layer, at least two intermediate lines 430, and the lower wiring layer may be formed in the shape of steps or the shape of inverse steps to be different from each other in the extending lengths.

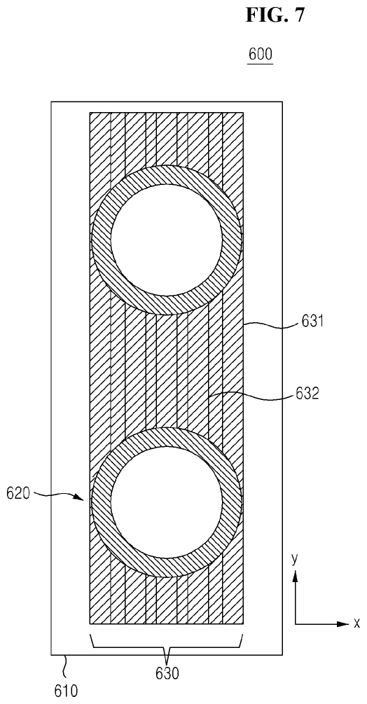

FIG. 6 is an x-z cross-sectional view illustrating a 3D flash memory according to another embodiment, and FIG. 7 is an x-y cross-sectional view illustrating a 3D flash memory according to another embodiment.

Referring to FIGS. 6 to 7, a 3D flash memory 600 according to an embodiment includes a substrate 610, at least one string 620 extending in one direction on the substrate 610, and at least two intermediate lines 630 disposed at an intermediate point in a direction in which the at least one string 620 extends and connected to at least one string 620.

The 3D flash memory 600 according to another embodiment has the same components as those of the 3D flash memory 400 described with reference to FIGS. 4 to 5, except for only a portion of the structure of the at least two intermediate lines 430. Accordingly, the details of only the at least two intermediate lines 430 will be described below.

The at least two intermediate lines 630 may be formed of at least one of a metal conductive material (e.g., tungsten (W), titanium (Ti), tantallium (Ta), copper (Cu), or gold (Au)), such that the at least two intermediate lines 630 may fixedly be used for at least one string 620 while serving as mutually different electrodes of a source electrode or a drain electrode, respectively. For example, the at least two intermediate lines 630 may be formed to extend in the y-direction.

In this case, the wording “the at least two intermediate lines 630 may be fixedly used for the at least one string 620 while serving as mutually different electrodes of the source electrode or the drain electrode, respectively” refers to that any one intermediate line 630 of the at least two intermediate lines 630 is fixedly used for fixed to any one (e.g., an upper string 623) of at least one upper string 623 or at least one lower string 624, which is obtained by dividing the at least one string 620 into two parts by at least two intermediate lines 630, while serving as the source electrode, and a remaining one intermediate line 632 is fixedly used for a remaining one string (e.g., the at least one lower string 624) of the at least one upper string 623 or the at least one lower string 624 while serving as the drain electrode.

In other words, the at least two intermediate lines 630 may include at least one intermediate source line 631 serving as a source electrode for the at least one string 620, and at least one intermediate drain line 632 serving as a drain electrode for the at least one string 620. Hereinafter, although the at least two intermediate lines 630 include one intermediate source lines 631 and five intermediate drain lines 632, the number of intermediate lines are not limited thereto.

The at least two lines 630 are configured in mutually different layers as illustrated in the drawing to have mutually independent wiring structures, such that the at least two lines 630 may be separated independently from each other. For example, at least one intermediate source line 631 and at least one intermediate drain line 632 may be separated from each other by being disposed to be spaced apart from each other by a specific distance from in the vertical direction in mutually different layers. In more detail, for example, the at least one intermediate source line 631 is disposed above and the at least one intermediate drain line 632 is disposed below, such that the at least one intermediate source line 631 and the at least one intermediate drain line 632 are separated from each other. Hereinafter, the wording “the at least two lines 630 are configured in mutually different layers” may refer to that the at least two lines is configured (be separated from each other in one intermediate layer) in mutually different layers within one intermediate wiring layer positioned on the same plane.

As described above, since at least two intermediate lines 630 should be used as mutually different electrodes for at least one upper string 623 or at least one lower string 624, such that the at least two intermediate lines 430 may be connected to mutually different strings of the at least one upper string 623 or the at least one lower string 624. For example, at least one intermediate source line 631 of the at least two intermediate lines 630 is connected to the at least one upper string 623 while fixedly serving as a source electrode. At least one intermediate drain line 632 may be connected to at least one lower string 624 while serving as a drain electrode.

The spacing between the at least two intermediate lines 430 (more exactly, the spacing of the at least one intermediate drain line 631) may be set to be in the range of 10 nm and 50 nm, based on the cross-sectional size of the at least one string 620, the number of at least two intermediate lines 630 (more exactly, the number of the at least one intermediate drain line 632), and the thickness of each of the at least two intermediate lines 630 (more exactly, the thickness of each of at least one intermediate drain line 632). For example, when considering that the cross-section diameter of at least one string 620 is 120 nm and the thickness of each of the two intermediate lines 632 is 10 nm, the spacing of the at least one intermediate line 632 may be set to be in the range of 10 nm and 50 nm, such that at least two intermediate lines 632 may be disposed within the cross-section of at least one string 620.

In addition, the at least two intermediate lines 630 are formed simultaneously with the metal of the transistor (not illustrated) included in the substrate 610 (the metal of the transistor and the at least two intermediate lines 630 are formed at the same time through the same process), thereby simplifying the manufacturing process.

In addition, at least two intermediate lines 630 may be shared and used by a plurality of strings when the 3D flash memory 600 includes a plurality of strings including at least one string 620. For example, at least one outer intermediate drain line 632 of the at least two intermediate drain lines 630 may be shared and used by strings adjacent to each other in a horizontal direction.

As described above, as the at least two intermediate lines 630 are included, the 3D flash memory 600 fixedly employs the different intermediate lines 631 and 632 as any one electrode of the intermediate source electrode or the intermediate drain, thereby reducing a circuit complexity in which a source electrode-related line or a drain electrode-related line are connected, and a control complexity in which at least two intermediates lines are controlled, in the structure including the intermediate wiring layer.

In addition, as the at least two intermediate lines 630 are included, the 3D flash memory 600 may form the drain doping 623-1 and 624-1 at the same positions, which are symmetrical to each other, in at least one lower string 624 and at least one upper string 623, which are obtained by dividing the at least one string 620 into two parts by the intermediate wiring layer, in the structure including the intermediate wiring layer. For example, the drain doping 623-1 and 624-1 may be formed at the same upper positions in the at least one lower string 624 and the at least one upper string 623. Accordingly, the manufacturing costs may be prevented from being increased as asymmetric drain junctions are formed in the structure including the intermediate wiring layer. For reference, the drain doping 623-1 and 624-1 are not illustrated in FIG. 6 for the illustrative purpose.

In addition, according to the 3D flash memory 600, the at least two intermediate lines 630 are formed in the shape of a step or an inverse step, together with the upper wiring layer disposed on the at least one string 620 and the lower wiring layer disposed under the at least one string 620, thereby simplifying a memory wiring process and improving the degree of integration. In addition, the 3D flash memory 600 may be configured such that the upper wiring layer, at least two intermediate lines 630, and the lower wiring layer have the shape of steps having lengths sequentially increased or the shape of inverse steps having lengths sequentially decreased, while extending in a direction perpendicular to an extension direction of the at least one string 620. In other words, the upper wiring layer, at least two intermediate lines 630, and the lower wiring layer may be formed in the shape of steps or the shape of inverse steps to be different from each other in the extending lengths.

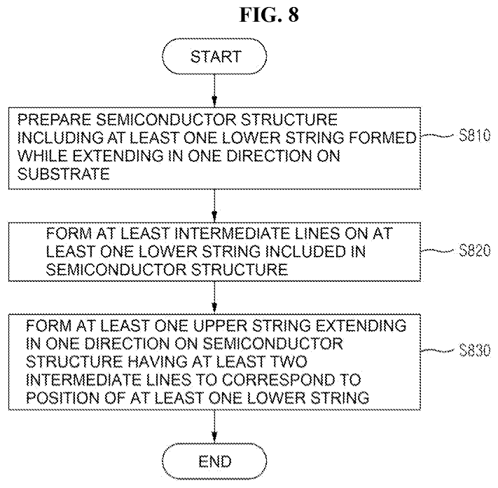

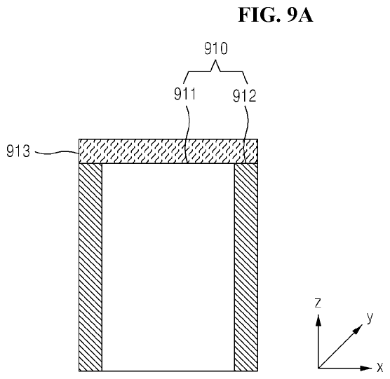

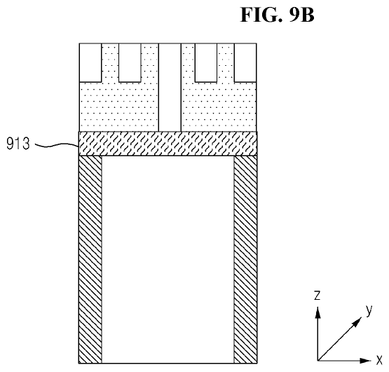

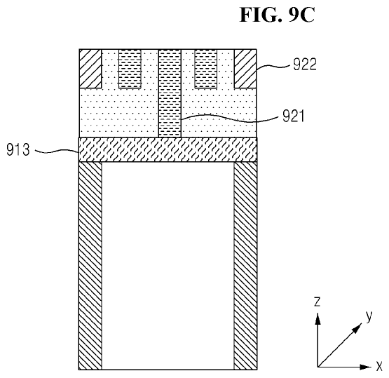

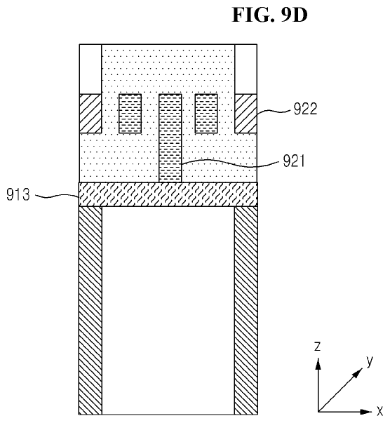

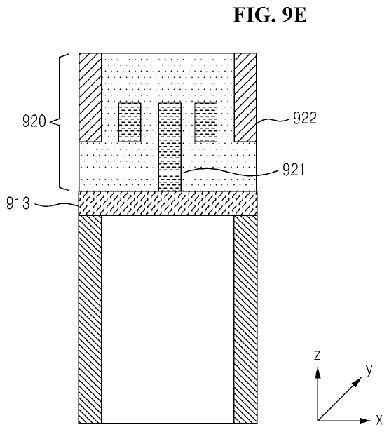

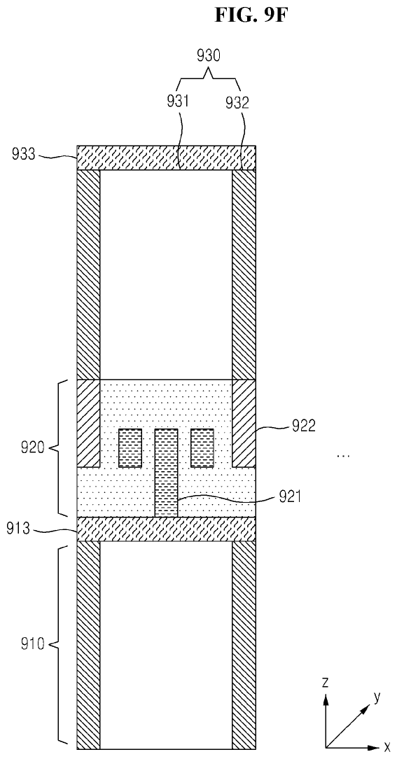

FIG. 8 is a flowchart illustrating a method for manufacturing a 3D flash memory according to an embodiment, FIGS. 9A to 9F are x-z cross-sectional views illustrating a method for manufacturing a 3D flash memory illustrated in FIGS. 4 to 5, and 10A to 10F are x-z cross-sectional views illustrating a method of manufacturing a 3D flash memory illustrated in FIGS. 6 to 7.

Hereinafter, on the assumption that the method for manufacturing the 3D flash memory described with reference to FIGS. 8 to 10F is performed by a manufacturing system, which is automated and mechanized, the method for manufacturing the 3D flash memory 400 described with reference to FIGS. 8 to 10F refers to the 3D flash memory 400 described above with reference to FIGS. 4 and 5, and the method for manufacturing the 3D flash memory 600 described above with reference to FIGS. 6 and 7.

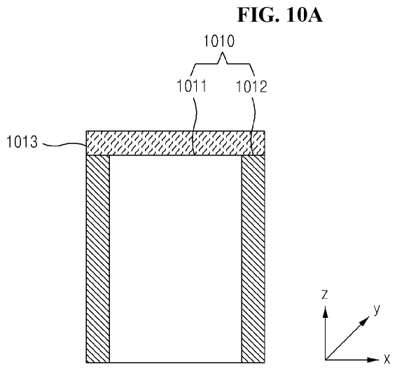

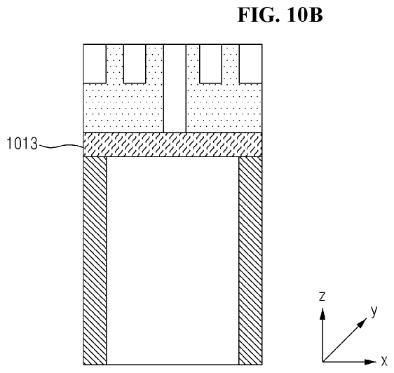

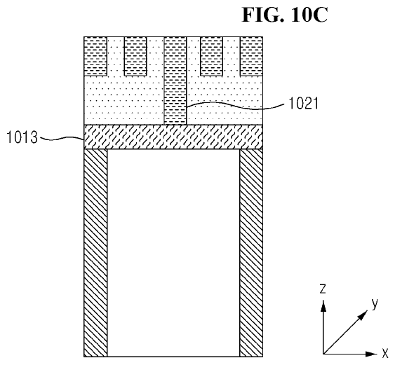

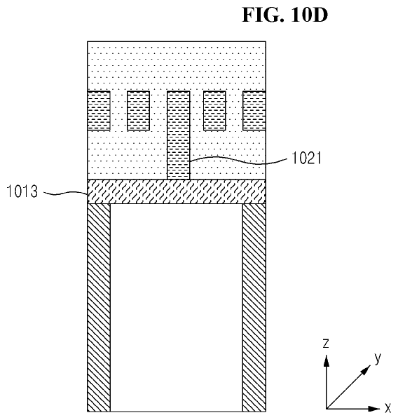

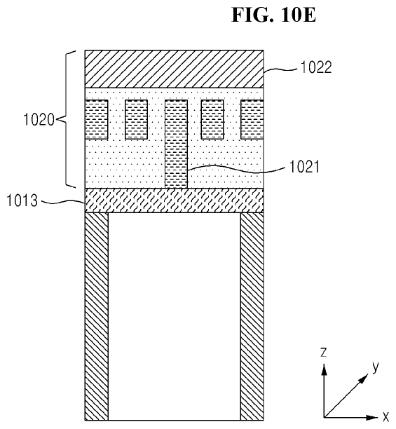

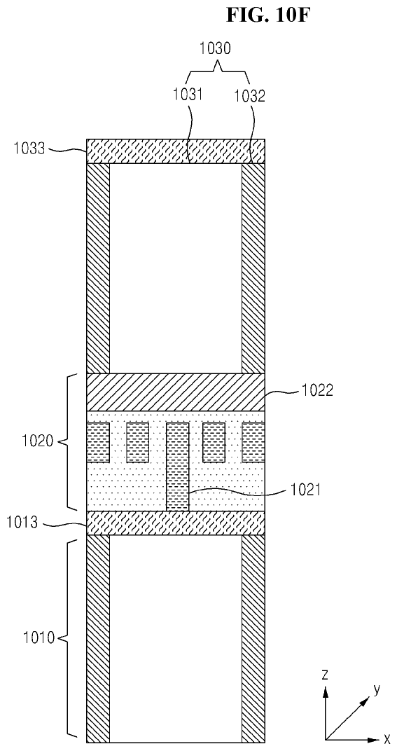

First, the manufacturing system may prepare a semiconductor structure including at least one lower string 910 or 1010 extending in one direction on the substrate in step S810, in which at least one lower string 910 or 1010 includes at least one lower channel layer 911 or 1011 and at least one lower charge storage layer 912 or 1012 formed to surround the at least one lower channel layer 911 or 1011. In this case, the drain doping 913 and 1013 may be formed at the upper portion of the at least one lower string 910 or 1010. The step S810 of preparing for the semiconductor structure may be performed as illustrated in FIG. 9A or 10A. Hereinafter, although the drawing briefly illustrates that the semiconductor structure includes on at least one lower string 910 or 1010, the semiconductor structure may further include a plurality of word lines or a plurality of insulating layers.

Thereafter, the manufacturing system may form at least two intermediate lines 430 formed on at least one lower string 910 or 1010 included in the semiconductor structure in step S820.

In more detail, in step S820, the manufacturing system may employ the at least two intermediate lines 920 and 1020 to be fixedly used for at least one string while serving as mutually different electrodes of the source electrode or the drain electrode, respectively, by separately forming at least one intermediate drain line 921 or 1021, which is used as a drain electrode for at least one string (at least one lower string 910 or 1010) and at least one upper string 930 or 1030) of the at least two intermediate lines 920 and 1020 and at least one intermediate source line 922 or 1022 used as a source electrode for at least one string.

In this case, the wording “separately forming at least one intermediate drain line 921 or 1021 and at least one intermediate source line 922 or 1022” may refer to that the at least one intermediate drain line 921 or 1021 and the at least one intermediate source line 922 or 1022 are separately formed to be connected to mutually different strings of the at least one lower string 910 or 1010 and the at least one upper string 930 or 1030.

In particular, the manufacturing system may separately form the at least one intermediate drain line 921 or 1021 and the at least one intermediate source line 922 or 1022 in a single layer as illustrated in FIGS. 9B to 9E, or may form the at least one intermediate drain line 921 or 1021 and the at least one intermediate source line 922 or 1022 in mutually different layers as illustrated in FIGS. 10B to 10E, in step S820.

For example, the manufacturing system may manufacture at least two intermediate lines 920, by performing a Damascene process of forming an insulating layer including trenches for a remaining portion of at least one source line 922 and filling a conductive material in trenches to form a remaining portion of the at least one intermediate source line 922, as illustrated in FIG. 9D to 9E, after performing a Damascene process of forming the insulating layer including the trenches on at least one lower string 910 included in the semiconductor structure and filling the conductive material in the trenches to at least partially form at least one intermediate drain line 921 and at least one intermediate source line 922 of the at least two intermediate lines 920, as illustrated in FIG. 9B to 9C.

For another example, the manufacturing system may manufacture at least two intermediate lines 1020 by performing a Damascene process of forming an insulating layer and depositing a conductive material on the resultant structure to form at least one source line 1022 as illustrated in FIGS. 10D to 10E, after performing a Damascene process of forming an insulating layer including trenches on the at least one lower string 1010 included in the semiconductor structure and filling the conductive material in the trenches to form at least one intermediate drain line 1021 of the at least two intermediate lines 1020 as illustrated in FIG. 10B to 10C.

In addition, although not illustrated in the drawing, the manufacturing system may form a metal of a transistor included in the substrate in step S820. In other words, the manufacturing system may simultaneously perform a process of forming the metal of the transistor included in the substrate and a process of forming at least two intermediate lines 920 and 1020 in step S820.

Accordingly, the manufacturing system may form at least one upper string 930 or 1030, which includes at least one upper channel layer 931 or 1031 extending in one direction and at least one upper charge storage layer 932 or 1032 formed to surround the at least one upper channel layer 931 or 1031, on the semiconductor structure having at least two intermediate lines 920 or 1020 while extending in one direction to correspond to a position of at least one lower string 910 or 1010 as illustrated in FIG. 9F or 10F in step S830.

In this case, the manufacturing system may form drain doping 933 or 1033 on at least one upper string 930 or 1030 to be symmetrical to positions for the drain doping 913 or 1013, which is formed on at least one lower string 910 or 1010 in step S810, in step S830.

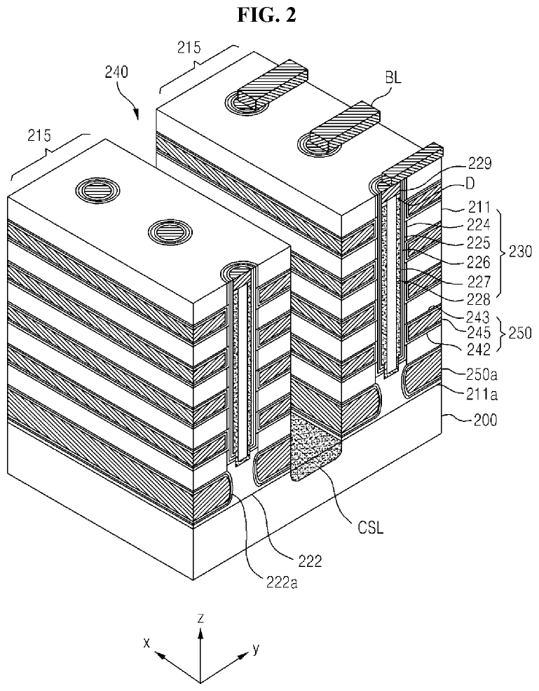

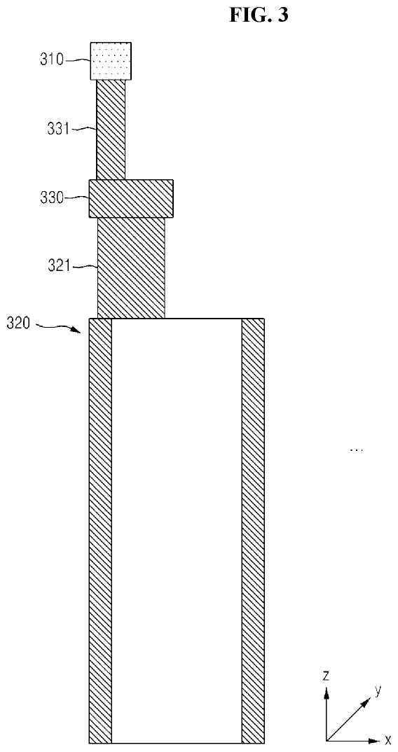

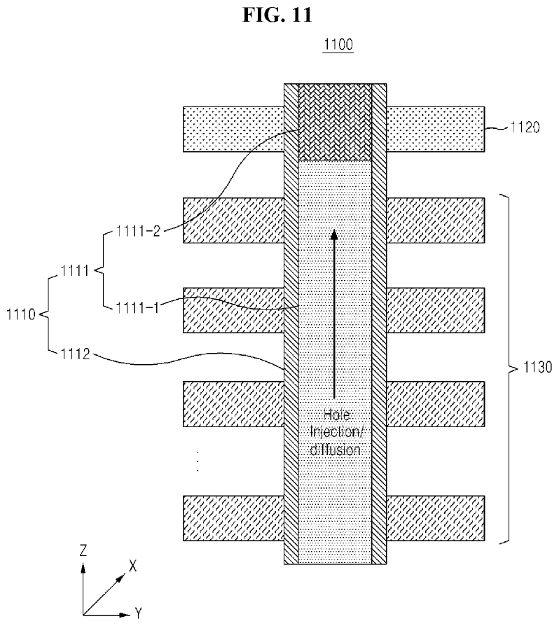

FIG. 11 is a Y-Z cross-sectional view illustrating a 3D flash memory according to an embodiment. Hereinafter, a 3D flash memory 1100 according to an embodiment may be illustrated and described without components such as a substrate, a bit line positioned on the string, and a source line positioned under the string for the convenience of explanation. However, the 3D flash memory 1100 according to an embodiment is not limited thereto, and may further include additional components based on the structure of the conventional 3D flash memory illustrated in FIG. 2. In addition, although the 3D flash memory 1100 according to an embodiment is illustrated and described as including one string, the present disclosure is not limited thereto. For example, the 3D flash memory 1100 according to an embodiment may include a plurality of strings. In this case, a structure of one string to be described below may be applied to each of the plurality of strings without change.

Referring to FIG. 11, a 3D flash memory 1100 according to an embodiment may include a string 1110, at least one selection line 1120, and a plurality of word lines 1130. Hereinafter, the 3D flash memory 1100 may essentially include a string 1110, at least one selection line 1120, and a plurality of word lines 1130, and may further include a plurality of insulating layers (not illustrated) interposed between the plurality of word lines 1130, a bit line disposed on the string 1110, and a source line disposed under the string 1110.

The string 1110 includes a channel layer 1111 and a charge storage layer 1112 while extending in one direction (e.g., a z direction) on a substrate, thereby forming memory cells corresponding to each of a plurality of word lines 1130 connected in the vertical direction. The charge storage layer 1112 is a component to store charges resulting from a voltage applied through the plurality of word lines 1130, while extending to surround the channel layer 1111. The charge storage layer 1112 may serves as a data storage in the 3D flash memory 1100, may be formed in an oxide-nitride-oxide (ONO) structure or may include a ferroelectric film such as HfOx. The channel layer 1111 may include a first region 1111-1 formed of single crystalline silicon or polysilicon and a second region 1111-2 formed of an oxide semiconductor material, and may further include a buried layer (not illustrated) filled in the channel layer 1111. The structure of the channel layer 1111 will be described in more detail below.

The at least one selection line 1120 may serve as any one of at least one string selection line (SSL) (the at least one string selection line is connected to a bit line (not illustrated) positioned on the string 1110) on the string 110 in the vertical direction or at least one ground selection line (at least one ground selection line is connected to a source line (not illustrated) positioned at a lower portion the string 1110) connected to the lower portion of the string 1110 in the vertical direction, and may include a conductive material such as tungsten (W), titanium (Ti), tantallium (Ta), copper (Cu), or gold (Au).

Hereinafter, although at least one selection line 1120 is illustrated as one string selection line as in drawing, the present disclosure is not limited as described above. The case that the at least one selection line 1120 is realized in plural (two) adjacent to any one of the upper portion or the lower portion of the string will be described with reference to FIG. 6.

The plurality of word lines 1130 may be positioned at the upper portion or the lower portion of the at least one selection line 1120 and connected to the string 1110 in the vertical direction, may include a conductive material such as tungsten (W), titanium (Ti), tantallium (Ta), copper (Cu), or gold (Au), and may apply a voltage to the memory cells corresponding to the plurality of word lines 1130 to perform an operation (a read operation, a program operation, and an erase operation).

In particular, according to an embodiment, the 3D flash memory 1100 may form the channel layer 1111 by dividing regions based on composite materials. In more detail, the channel layer 1111 may include a first region 1111-1 corresponding to a plurality of word lines 1130 and a second region 1111-2 corresponding to at least one selection line 1120, in which the first region 111-1 and the second region 111-2 include mutually different materials. For example, the channel layer 1111 may include the second region 111-2 disposed to correspond to the position at least one selection line 1120 on the channel layer 1111 and including an oxide semiconductor material, and the first region 1111-1 disposed on the upper portion or the lower portion of the second region 1111-2 and including single crystalline silicon or polysilicon. Hereinafter, the oxide semiconductor material may include a material including at least one of In, Zn, or Ga (e.g., a ZnOₓ-based material including AZO, ZTO, IZO, ITO, IGZO, or Ag—ZnO) or a group IV semiconductor material. In addition, the wording “the first region 1111-1 is disposed at the upper portion or the lower portion of the second region 1111-2” may refer to that the first region 1111-1 is disposed on the channel layer 1111 to correspond to the positions of the plurality of word lines 1130.

In the channel layer 1111 having the structure, the second region 1111-2 may be used to block a leakage current for at least one selection line 1120 and to improve transistor characteristics of at least one selection line 1120, and the first region 1111-1 may be used to spread the injected hole to the entire region of the memory cells. For example, the second region 1111-2 may be formed of an oxide semiconductor material having excellent leakage current characteristics, which may block and suppress the leakage current in the first region 1111-1 of the channel layer 1111 and improve a speed and threshold voltage distribution when at least one selection line 1120 selects the string 1110 in the reading operation or the program operation. The first region 1111-1 is formed of the silicon-based material representing excellent hole mobility, thereby spreading holes injected from a bulk of the substrate into the entire region of the memory cells.

In this case, the second region 1111-2 may have a cross-section of the same size as the cross-section of the channel layer 1111, and may have a shape that completely covers one of the upper or lower surfaces of the first region 1111-1. Accordingly, the second region 1111-2 may completely block and suppress the leakage current in the first region 1111-1 of the channel layer 1111.

As described above, according to an embodiment, the 3D flash memory 1100 may form the channel layer 1111 having the first region 1111-1 and the second region 1111-2, thereby performing a memory operation based on hole injection as holes are injected from the bulk of the substrate through the first region 1111-1, and suppressing and blocking the leakage current caused in the memory operation through the second region 1111-2, such that the leakage current characteristic is improved. In addition, transistor characteristics of at least one selection line 1120 (the threshold voltage distribution of string cells and the speed of program/reading operations) may be improved

In addition, although not illustrated in the drawings, the second region 1111-2 may further include an N-type junction formed at a contact interface with the first region 1111-1. The N-type junction may be formed by performing N-type doping, and may reduce contact resistance between the first region 1111-1 and the second region 1111-2.

As described above, although at least one selection line 1120 is one string selection line or one ground selection line, a plurality of selection lines, which are like two string selection lines or two ground selection lines, may be realized to be adjacent to each other in the vertical direction. Hereinafter, the details thereof will be described with reference to FIG. 6.

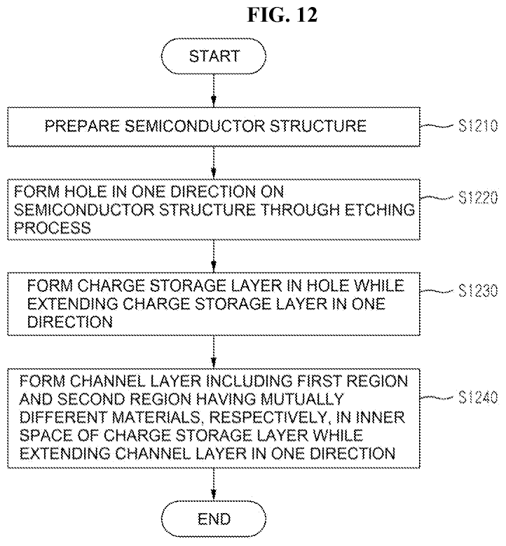

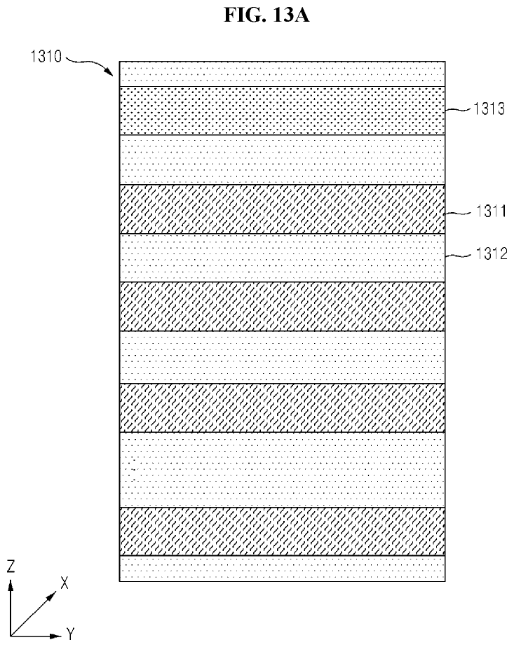

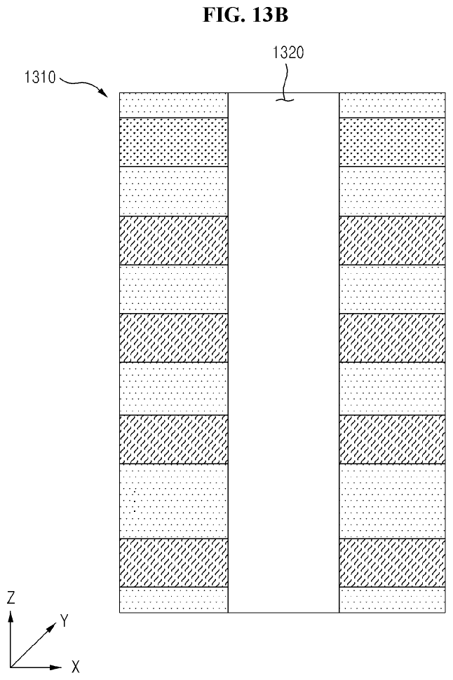

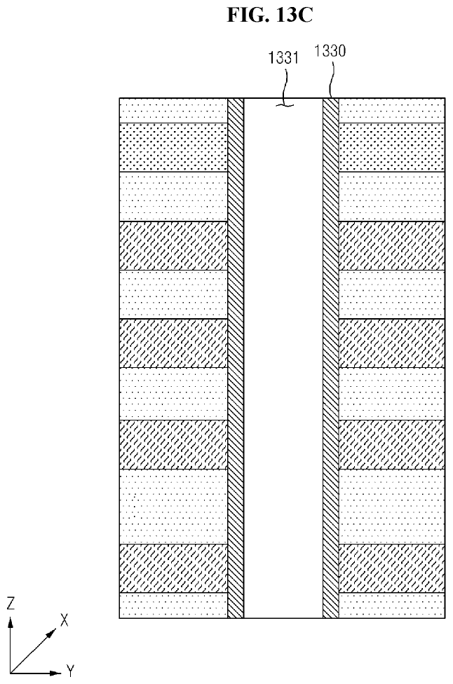

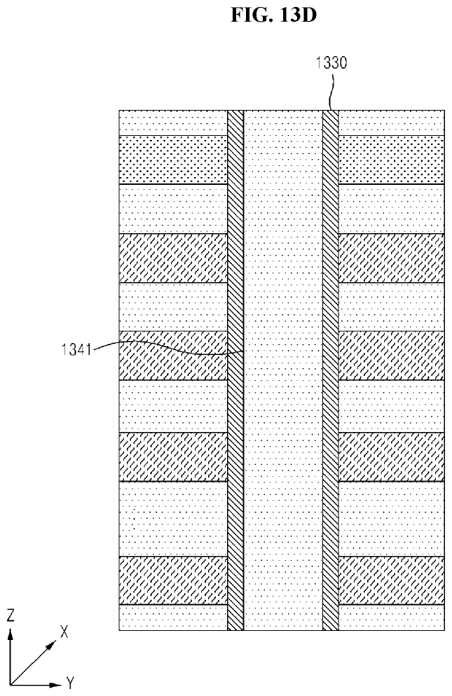

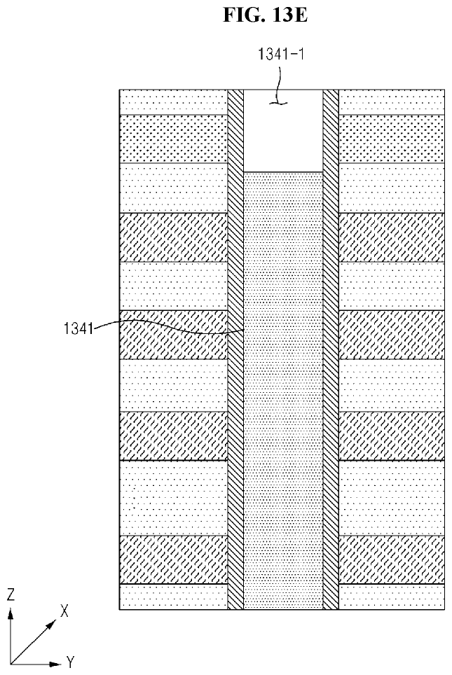

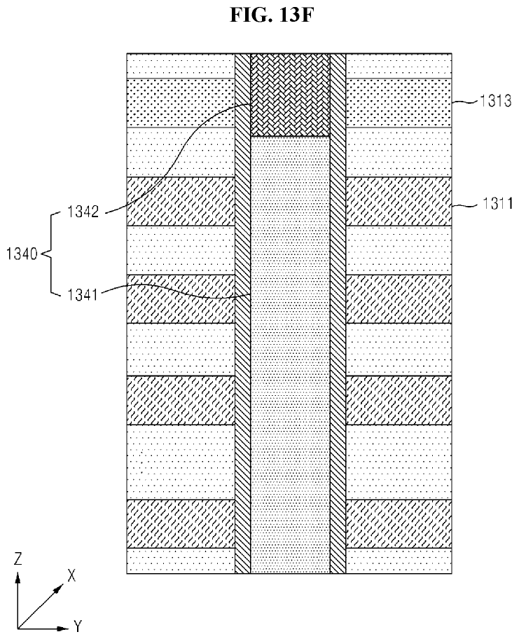

FIG. 12 is a flowchart illustrating a method for manufacturing a 3D flash memory according to an embodiment, and FIGS. 13A to 13F are a Y-Z cross-sectional views illustrating a method of manufacturing a 3D flash memory according to an embodiment. On the assumption the method for manufacturing the 3D flash memory described below is assumed to be performed by an automated and mechanized manufacturing system, the method may refer to the method for manufacturing the 3D flash memory 1100 described above with reference to FIG. 11.

First, in step S1210, the manufacturing system may prepare a semiconductor structure 1310 having a plurality of word lines 1311 and a plurality of insulating layers 1312 alternately stacked on a substrate, and at least one selection line 1313 stacked on an upper portion or a lower portion of the semiconductor structure 1310.

In this case, at least one selection line 1313 in the semiconductor structure 1310 is any one of at least one string selection line SSL or at least one ground selection line GSL, and may be formed of the conductive material, such as tungsten (W), titanium (Ti), tantallium (Ta), copper (Cu), or gold (Au). In addition, even the plurality of word lines 1311 in the semiconductor structure 1310 may be formed of the conductive material such as tungsten (W), titanium (Ti), tantallium (Ta), copper (Cu), or gold (Au). To the contrary, the plurality of insulating layers 1312 in the semiconductor structure 1310 may be formed of an insulating material.

Hereinafter, although drawings illustrate that at least one selection line 1313 is stacked at the upper portion of the semiconductor structure 1310, the present disclosure is not limited thereto. Similarly, even when the at least one selection line 1313 is stacked at the lower portion of the semiconductor structure 1310, the 3D flash memory may be manufactured through steps S1210 to S1240.

Thereafter, in step S120, the manufacturing system may form a hole 1320, which extends in one direction, in the semiconductor structure 1310 through an etching process. In this case, the hole 1320 refers to a trench having a circular shape.

Next, in step S1230, the manufacturing system may form the charge storage layer 1330, which extends in one direction (e.g., a z direction), in the hole 1320, as illustrated in FIG. 13C. For example, the manufacturing system may form the charge storage layer 1330 on an inner wall of the hole 1320 such that the charge storage layer 1330 has an inner space 1331.

Thereafter, in step S1240, the manufacturing system may form the channel layer 1340, which includes a first region 1341 corresponding to the plurality of word lines 1311 and a second region 1342 corresponding to at least one selection line 1313, in the inner space 1331 of the charge storage layer 1330, such that the channel layer 1340 includes different materials depending on regions and extends in one direction (e.g., the z direction). In more detail, the manufacturing system may form the first region 1341 using single crystalline silicon or polysilicon, and may form the second region 1342 using an oxide semiconductor material. Hereinafter, the oxide semiconductor material may include a material including at least one of In, Zn, or Ga (e.g., a ZnOₓ-based material including AZO, ZTO, IZO, ITO, IGZO, or Ag—ZnO) or a group IV semiconductor material.

For example, when at least one selection line 1313 is stacked at the upper portion of the semiconductor structure 1310, the manufacturing system may form the first region 1341 to correspond to the positions of the plurality of word lines 1311 and then the second region 1342 to correspond to the positions of at least one selection line 1313. For another example, when at least one selection line 1313 is stacked at the lower portion of the semiconductor structure 1310, the manufacturing system may form the second region 1342 to correspond to the position of at least one selection line 1313 and then form the first region 1341 to correspond to the positions of the plurality of word lines 1311.

In this case, in step S1240, the manufacturing system may form the second region 1342 using the oxide semiconductor material representing the excellent leakage current characteristic, such that the second region 1342 blocks the leakage current for the at least one selection line 1313 and improve the transistor characteristic of the at least one selection line 1313, and may form the first region 1341 using silicon-based material representing excellent hole mobility such that the first region 1341 is used to spread injected holes into the entire region of the memory cells.

In addition, in step S1240, the manufacturing system may form the second region 1342 to have the cross-section having an equal size to that of the cross-section of the channel layer 1340, such that the second region 1342 has the shape of completely covering one surface of the top surface or the bottom surface of the first region 1341, thereby completely blocking and suppressing the leakage current in the first region 1341.

In addition, the manufacturing system may reduce contact resistance between the first region 1341 and the second region 1342 by forming an N-type junction at the contact interface between the first region 1341 and the second region 1342 in S1240.

As an example of step S1240, when at least one selection line 1313 is stacked on the semiconductor structure 1310, the manufacturing system may form the first region 1341 formed of single crystalline silicon or polysilicon in the inner space 1331 of the charge storage layer 1330 as illustrated in FIG. 13D, may form a recess in a portion of an upper region, which corresponds to the at least one selection line 1313, of the first region 1341 as illustrated in FIG. 13E, may form the second region 1342 using an oxide semiconductor material in the recessed space 1341-1 as illustrated in FIG. 13F, and may perform a planarization, thereby forming the channel layer 1340 including composite channel materials of the first region 1341 and the second region 1342.

When the at least one selection line 1313 is stacked at the lower portion of the semiconductor structure 1310, the manufacturing system may form the second region 1342 using the oxide semiconductor material up to the height corresponding to at least one selection line 1313 in the inner space of the charge storage layer 1330, may planarize the resultant structure, and may form the first region 1341 on the planarized structure using the single crystalline silicon or the polysilicon, thereby forming the channel layer 1340 including the composite channel materials of the first region 1341 and the second region 1343.

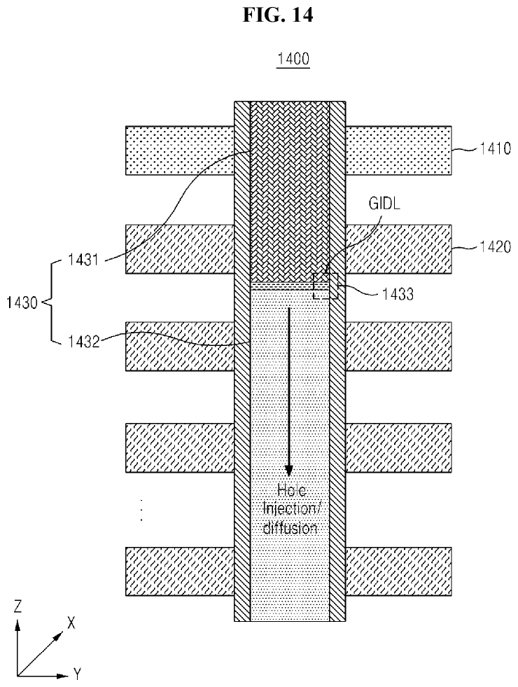

FIG. 14 is a Y-Z cross-sectional view illustrating a 3D flash memory according to an embodiment.

Referring to FIG. 14, according to another embodiment, a 3D flash memory 1400 has the same component structure as that of the 3D flash memory 1100 described above with reference to FIG. 11 except for at least one selection line 1410 or 1420. In the following description, only the at least one selection line 1410 or 1420, and a second region 1431 of a channel layer 1430 connected vertically to the at least one selection line 1410 or 1420 will be described.

According to another embodiment, as the 3D flash memory 1400 includes two selection lines 1410 or 1420 adjacent to each other in a vertical direction, the second region 1431 blocks the leakage current for an upper selection line 1410 of the two selection lines 1410 and 1420 and improves the characteristic of the transistor of the at least one selection line 1410 or 1420. In addition, the second region 1431 is used to inject holes into the first region 1432 through the N-type junction 1433 related to the lower selection line 1420 of the two selection lines 1410 and 1420 and formed on the contact interface between the first region 1432 and the second region 1431

In more detail, as the second region 1431 is formed of an oxide semiconductor material representing the excellent leakage current characteristic to block and suppress the leakage current flowing to the upper selection line 1410 in the first region 1432, and improve a speed and threshold voltage distribution when selecting the at least one selection line 1410 or 1420 in the reading operation or the program operation. In addition, as the second region 1431 includes the N-type junction 1433, the second region 1431 injects holes resulting from a GIDL phenomenon in the N-type junction 1433, into the first region 1432, in response to the voltage applied from the lower selection line 1420 of the two selection lines 1410 or 1420.

In this case, the first region 1432 is formed of single crystalline silicon or polysilicon representing excellent hole mobility to spread hole injected due to the GIDL phenomenon in the N-type junction 1433 into the entire region of the memory cells.

As described above, according to another embodiment, the 3D flash memory 1400 includes the channel layer 1430 having the first region 1432 and the second region 1431 and disposes the second region 1441 to correspond to the positions of the two selection lines 1410 or 1420, thereby performing a memory operation based on hole injection as a hole is injected into the first region 1432 due to the Gate Induced Drain Leakage (GIDL) in the N-type junction 1433, and blocking and suppressing the leakage current caused in the memory operation through the second region 1431, thereby improving the leakage current characteristic. In addition, transistor characteristics of at least one selection line 1420 (the threshold voltage distribution of string cells and the speed of program/reading operations) may be improved

The 3D flash memory 1400 having such a structure is the same as the 3D flash memory 1100 described above with reference to FIG. 11 except for the number of at least one selection line 1410 or 1420 in terms of a structure. Accordingly, the 3D flash memory 1400 may be manufactured through steps S1210 to S1240 described with reference to FIGS. 12 and 13A to 13F. However, when the 3D flash memory 1400 is manufactured, the manufacturing system differs from the manufacturing method of the 3D flash memory 1100 described above with reference to FIG. 11, in terms of preparing a semiconductor structure including a plurality of word lines and a plurality of insulation layers alternately stacked on the substrate and two selection lines provided at any one of an upper portion or a lower portion thereof and adjacent to each other in the vertical direction in step S1210.

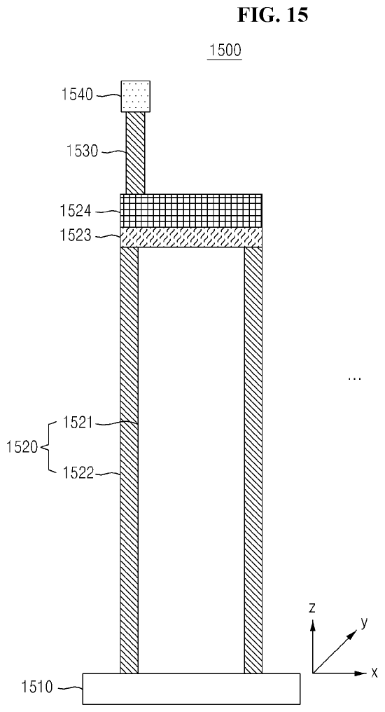

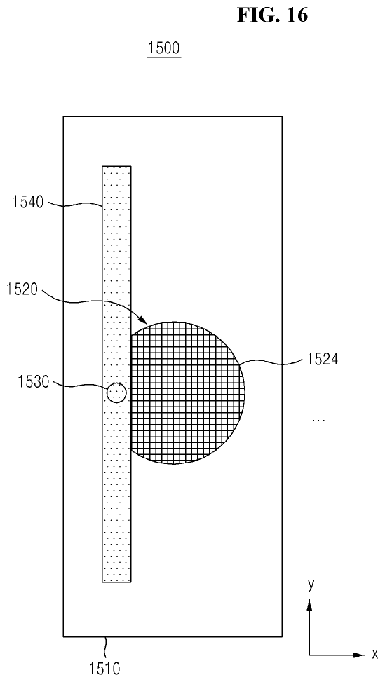

FIG. 15 is an x-z cross-sectional view illustrating a 3D flash memory according to another embodiment, and FIG. 16 is an x-y cross-sectional view illustrating a 3D flash memory according to another embodiment.

Referring to FIGS. 15 to 16, a 3D flash memory 1500 according to an embodiment may include a substrate 1510, at least one string 1520 extending in one direction (e.g., z-direction) on the substrate 1510, at least one plug line 1530 formed on at least one string 1520, and at least one bit line 1540 connected to at least one string 1520 through the at least one plug line 1530.

Hereinafter, the 3D flash memory 1500 may further include a plurality of word lines (not illustrated), a plurality of insulating layers (not illustrated), while essentially including the substrate 1510, the at least one string 1520, the at least one plug line 1530, and the at least one bit line 1540.

The at least one string 1520 includes at least one channel layer 1521 extending in one direction (e.g., the z direction) and at least one charge storage layer 1522 formed to surround the at least one channel layer 1521. The at least one charge storage layer 1522, which is a component to store charges resulting from a voltage applied through the plurality of word lines (not illustrated) serves as a data storage in the 3D flash memory 1500, and may be formed in a structure of ONO (Oxide-Nitride-Oxide). The at least one channel layer 1521 may be formed of single crystalline silicon or polysilicon and may be disposed in the form of an internal hollow tube. In this case, a buried layer (not illustrated) may be further disposed to fill the inside of the at least one channel layer 1521. Accordingly, at least one string 1520 may constitute memory cells corresponding to the plurality of word lines connected in a vertical direction. In addition, a drain doping (the N+ doping) 1523 may be formed at an upper portion of the at least one string 1520.

The at least one bit line 1540 may be formed of a conductive material such as tungsten (W), titanium (Ti), tantallium (Ta), copper (Cu), or gold (Au), while extending in a direction perpendicular to one direction (e.g., the y direction) in which the at least one string 1520 extends, thereby applying a voltage to the at least one string 1520.

The at least one plug line 1530 may be formed of a conductive material, such as cobalt (Co), silicide, molybudeum (Mo), cerium (Ce), tungsten (W), titanium (Ti), tantalium (Ta), copper (Au), or gold (Au) while extending in one direction (e.g., +z direction) to be connected to a upper portion of the at least one string 1520, and may be manufactured in a fine thickness (e.g., in the range of 10 nm to 50 nm) by considering the cross-sectional diameter of the at least one string 1520. To this end, the at least one plug line 1530 may be formed on the at least one string 1520 through an extreme ultraviolet (EUV) process, which is a lithographic process using extremely ultraviolet (ultraviolet). For example, when a cross-section diameter of the at least one string 1520 is 120 nm, and when at least one different string (not illustrated) positioned in the same column (e.g., adjacent in the y direction) or in the same row (e.g., adjacent in the x direction) as those of the at least one string 1520 is provided two times, the at least one plug line 1530 may be formed at a fine thickness of 20 nm.

In this case, a position for forming at least one plug line 1530 on the at least one string 1520 may be determined based on a position for forming the at least one different plug line (not illustrated) of at least one different string (not illustrated) positioned in the same column or the same row as those of the at least one string 1520, on at least one different spring.

In this case, the at least one different string positioned in the same column or in the same row as those of the at least one string 1520 should be connected to at least one different bit line (not illustrated) positioned at the same height as that of at least one bit line 1540 connected to the at least one string 1520. Accordingly, at least one plug line 1520 to connect the at least one string 1520 to the at least one bit line 1540 should be offset from at least one different plug line to connect the at least one string to the at least one different bit line, on each string.

Accordingly, the position for forming the at least one plug line 1530 on the at least one string 1520 may be determined such that the position for forming the at least one plug line 1530 on the at least one string 1520 is offset from the position for forming the at least one different plug line on the at least one different string.

Hereinafter, the details thereof will be described with reference to FIGS. 7 to 8.

As described above, the 3D flash memory 1500 according to an embodiment has a structure in which at least one bit line 1540 is directly connected to at least one string 1520 through only at least one plug line 1530, without passing through a component other than the at least one plug line 1530. Accordingly, a strapping line is not included, which differs from a conventional structure, to reduce manufacturing costs for a line.

In addition, the 3D flash memory 1500 according to an embodiment may further include a contact metal pad 1524 formed on the at least one string 1520 to reduce contact resistance with the at least one plug line 1530. For example, the contact metal pad 1524 may be formed of a metal material on the entire region of an upper portion of the at least one string 1520 (in more detail, the contact metal pad 1524 is formed on the drain doping 1523 formed on the at least one string 1520). In this case, the metal material forming the contact metal pad 1524 may be the same material as a conductive material (cobalt (Co), silicide, molybdenum (Mo), cerium (Ce), tungsten (W), titanium (Ti), tantalium (Ta), copper (Cu), or gold (Au)) constituting the at least one plug line 1530.

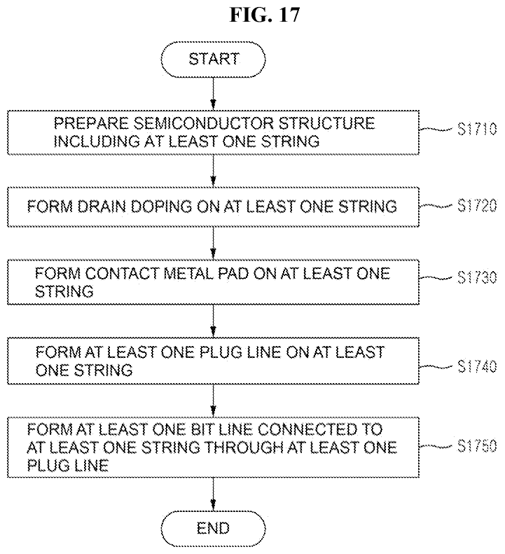

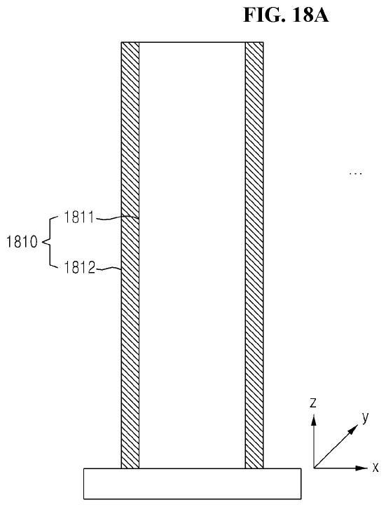

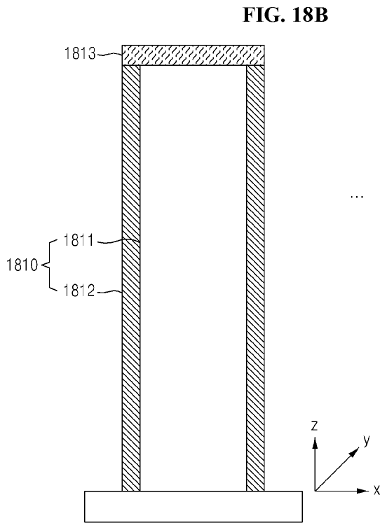

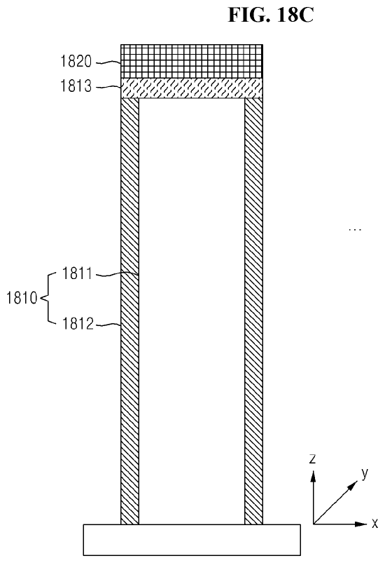

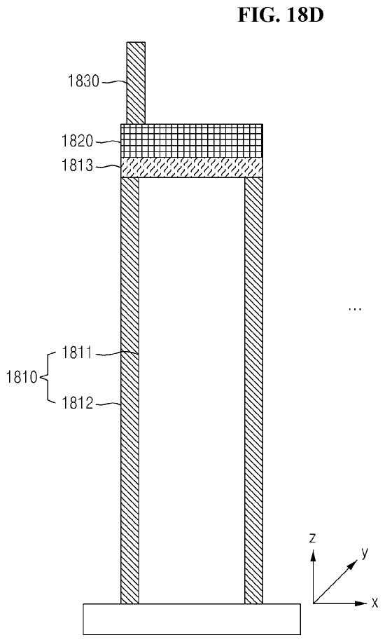

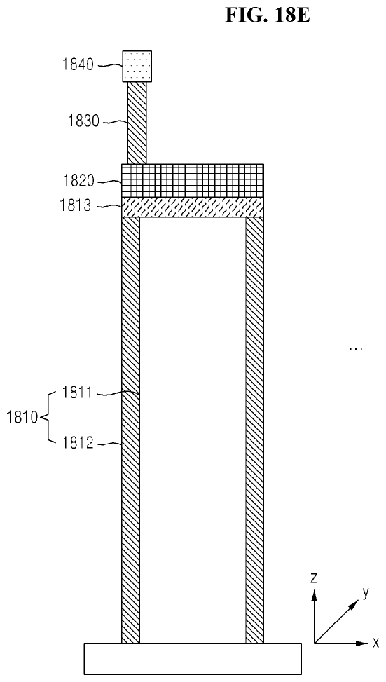

FIG. 17 is a flowchart illustrating a method for manufacturing a 3D flash memory according to an embodiment, and FIGS. 18A to 18F are a x-z cross-sectional views illustrating a method for manufacturing a 3D flash memory according to an embodiment.

On the assumption the method for manufacturing the 3D flash memory described with reference to FIGS. 17 to 18E is assumed to be performed by an automated and mechanized manufacturing system, the method may refer to the method for manufacturing the 3D flash memory 1500 described above with reference to FIGS. 15 to 16.

First, the manufacturing system may prepare a semiconductor structure including at least one lower string 1810 extending in one direction on the substrate in step S1710, in which at least one string 1810 includes at least one channel layer 1811 and at least one charge storage layer 1812 formed to surround the at least one channel layer 1811, as illustrated in FIG. 18A. Hereinafter, although the drawing illustrates that the semiconductor structure includes only at least one string 1810 in brief, the semiconductor structure may further include a plurality of word lines (not illustrated) and a plurality of insulating layers (not illustrated) connected to the at least one string 1810 in a vertical direction.

Subsequently, in step S1720, the manufacturing system may form drain doping (N+ doping) 1813 on at least one string 1810 as illustrated in FIG. 18B.

The manufacturing system may perform one integrated step S1710) like preparing a semiconductor structure having the drain doping 1813 formed on at least one string 1810, instead of performing step S1720 of forming the drain doping 1813 separately from step S1710 of preparing the semiconductor structure.

Next, in step S1730, the manufacturing system may form the contact metal pad 1820 on at least one string 1810 included in the semiconductor structure as illustrated in FIG. 18C. In this case, the contact metal pad 1820 may be formed of a metal material applied on the entire region of the upper portion of the at least one string 1810 to reduce contact resistance with the at least one plug line 1830 to be formed in step S1740 to be described later. For example, the contact metal pad 1820 may be formed of a metal material including at least one of cobalt (Co), silicide, molybdenum (Mo), cerium (Ce), tungsten (W), titanium (Ti), tantalium (Ta), copper (Cu), or gold (Au). A process of forming the metal pad 1820 may include various processes such as a Silicidation process or a chemical mechanical polishing (CMP) process in detail.

Similarly, the manufacturing system may perform one integrated step (S1710) like preparing the semiconductor structure having the contact metal pad 1820 formed on the at least one string 1810, instead of performing step S1730 of forming the contact metal pad 1820 separately from step S1710 of preparing the semiconductor structure. In this case, the manufacturing system may prepare the semiconductor structure including the at least one string 1810 (in detail, the contact metal pad 1820 is formed on the drain doping 1813 of at least one string 1810) having the contact metal pad 1820 formed thereon in step S1710.

Next, in step S1740, the manufacturing system may form at least one contact metal pad 1830 on the at least one string 1810 included in the semiconductor structure as illustrated in FIG. 18D. In more detail, the manufacturing system may form at least one plug line 1830 such that at least one bit line 1840 to be formed in step S1750 to be described later is directly connected to at least one string 1810 through at least one plug line 1830 without passing through components other than at least one plug line 1830. For example, the manufacturing system may form the at least one plug line 1830 by using a conductive material cobalt (Co), silicide, molybdenum (Mo), cerium (Ce), tungsten (W), titanium (Ti), tantalium (Ta), copper (Cu), or gold (Au) to have a fine thickness (e.g., in the range of 10 nm to 50 nm) based on the cross-section diameter of the at least one string 1820, while extending the at least one plug line 1830 in one direction (for example, the z direction) to be connected to an upper portion of the at least one string 1810. To this end, the at least one plug line 1830 may be formed on the at least one string 1810 through an extreme ultraviolet (EUV) process, which is a lithographic process using extreme ultraviolet (ultraviolet). For example, when a cross-section diameter of the at least one string 1810 is 120 nm, and when at least one different string (not illustrated) positioned in the same column (e.g., adjacent in the y direction) or in the same row (e.g., adjacent in the x direction) as those of the at least one string 1810 is provided two times, the at least one plug line 1830 may be formed at a fine thickness of 20 nm.

In this case, in step S1740, when forming at least one plug line 1830, the manufacturing system may consider at least one different plug line positioned in the same column or the same row as that of the at least one string 1810. In detail, in step S1740, the manufacturing system may determine a position for forming the at least one plug line 1830 on the at least one string 1810, based on the position for forming at least one different plug line of at least one different string, which is positioned in the same column or the same row as that of the at least one string 1810, on the at least one different string, and may form the at least one plug line 1830 on the at least one string 1810, depending on the determined position. In this case, the position for forming the at least one plug line 1830 on the at least one string 1810 may be determined such that the position for forming the at least one plug line 1830 on the at least one string 1810 is offset from the position for forming the at least one different plug line on the at least one different string.

Next, in step S1750, the manufacturing system may form at least one bit line 1840 connected to at least one string 1810 through at least one plug line 1830 as illustrated in FIG. 18E.

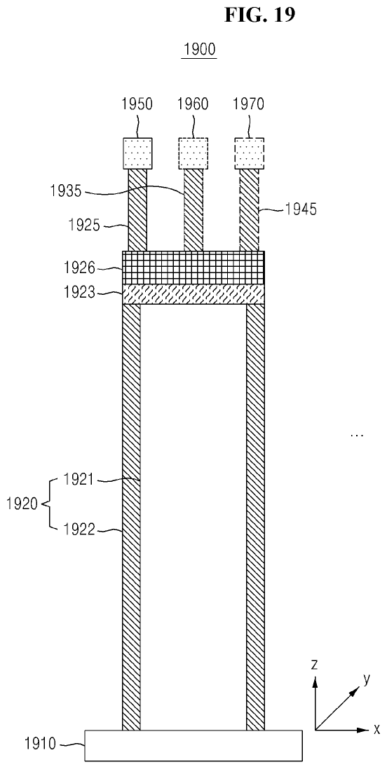

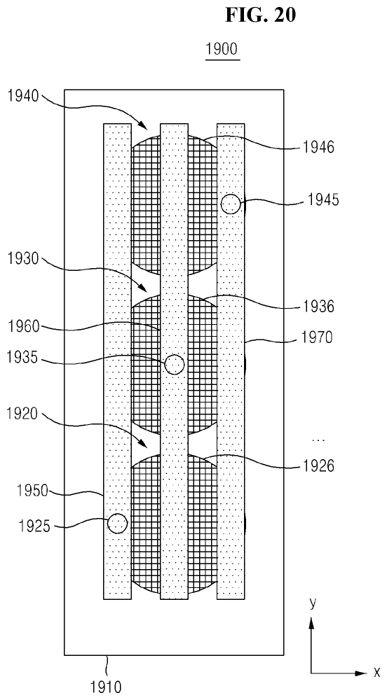

FIG. 19 is an x-z cross-sectional view illustrating a 3D flash memory according to another embodiment, and FIG. 20 is an x-y cross-sectional view illustrating a 3D flash memory according to another embodiment.

Referring to FIGS. 19 to 20, a 3D flash memory 1900 according to another embodiment may include a substrate 1910, a plurality of strings 1920, 1930, and 1940 extending in one direction (e.g., the z-direction) on the substrate 1910, a plurality of plug lines 1925, 1935, and 1950 formed on the plurality of strings 1920, 1930, and 1940, and a plurality of bit lines 1950, 1960, and 1970 connected to the plurality of strings 1920, 1930, and 1940, respectively, through the plurality of plug lines 1925, 1935, and 1950.

Hereinafter, the 3D flash memory 1900 may further include a plurality of word lines (not illustrated) and a plurality of insulating layers (not illustrated) interposed between the plurality of word lines (not illustrated) while essentially including the substrate 1910, the plurality of strings 1920, 1930, and 1940, the plurality of plug lines 1925, 1935, and 1945, and the plurality of bit lines 1950, 1960, and 1970.

The plurality of strings 1920, 1930, and 1940 are strings disposed in the same column or the same row. Each of the plurality of strings 1920, 1930, and 1940 may include a channel layer 1921 extending in one direction (e.g., the z direction) and a charge storage layer 1922 formed to surround the channel layer 1921. The at least one charge storage layer 1922, which is a component to store charges resulting from a voltage applied through the plurality of word lines (not illustrated), serves as a data storage in the 3D flash memory 1900, and may be formed in a structure of ONO (Oxide-Nitride-Oxide). The channel layer 1921 may be formed of single crystalline silicon or polysilicon and may be disposed in the form of an internal hollow tube. In this case, a buried layer (not illustrated) may be further disposed to fill the inside of the at least one channel layer 1921. Accordingly, each of the plurality of strings 1920, 1930, and 1940 may constitute memory cells corresponding to the plurality of word lines connected in the vertical direction. In addition, the drain doping (N+ doping) 1923 may be formed on each of the plurality of strings 1920, 1930, and 1940.

The plurality of bit lines 1950, 1960, and 1970 may be formed of a conductive material such as tungsten (W), titanium (Ti), tantallium (Ta), copper (Cu), or gold (Au), while extending in a direction perpendicular to one direction (e.g., the y direction) in which the plurality of strings 1920, 1930, and 1940 extends, thereby applying a voltage to the plurality of strings 1920, 1930, and 1940. For example, the plurality of bit lines 1950, 1960, and 1970 may be formed to correspond to the plurality of strings 1920, 1930, and 1940 to apply a voltage to relevant strings of the plurality of strings 1920, 1930, and 1940.

The plurality of bit lines 1950, 1960, and 1970 may be formed at an equal height on the plurality of strings 1920, 1930, and 1940 disposed in the same row or the same column, while being spaced apart from each other.

The plurality of plug lines 1925, 1935, and 1945 may be formed of a conductive material, such as cobalt (Co), silicide, molybudeum (Mo), cerium (Ce), tungsten (W), titanium (Ti), tantalium (Ta), copper (Au), or gold (Au) while extending in one direction (e.g., +z direction) to be connected to upper portions of the plurality of strings 720, 730, and 740, and may be manufactured in a fine thickness (e.g., in the range of 10 nm to 50 nm) by considering the cross-sectional diameter of the plurality of strings 1920, 1930, and 1940. To this end, the plurality of plug lines 1925, 1935, and 1945 may be formed on the plurality of strings 1920, 1930, and 1940 through an extreme ultraviolet (EUV) process, which is a lithographic process using extreme ultraviolet (ultraviolet). For example, when each of the plurality of strings 1920, 1930, and 1940 has a cross-sectional diameter of 120 nm and three strings are provided in one row as illustrated in the FIG. 19, each of the plurality of plug lines 1925, 1935, and 1945 may be formed to have a fine thickness of 20 nm.

In this case, positions for forming the plurality of plug lines 1925, 1935, and 1945 on the plurality of strings 1920, 1930, and 1940 may be determined complementarily from each other.

More specifically, the plurality of strings 1920, 1930, and 1940 should be disposed in the same column or the same row and connected to the plurality of bit lines 1950, 1960, and 1970 positioned at the same height. Accordingly, the plurality of plug lines 1925, 1935, and 1945 should be disposed to be offset from each other.

Accordingly, the positions for forming the plurality of plug lines 1925, 1935, and 1945 on the plurality of strings 1920, 1930, and 1940 may be offset from each other with respect to the plug lines 1925, 1935, and 1945.

Hereinafter, the wording “the plurality of plug lines 1925, 1935, and 1945 are arranged to be offset from each other, and the positions for forming the plurality of plug lines 1925, 1935, and 1945 on the plurality of strings 1920, 1930, and 1940 are offset from each other with respect to the plug lines 1925, 1935, and 1945” may refer to that the plurality of plug lines 1925, 1935, and 1945 are formed at mutually different positions on the plurality of strings 1920, 1930, and 1940. For example, the first plug line 1925 may be formed at a position biased to the left on the first string 1920, the second plug line 1935 may be formed at the center on the second string 1930, and the third plug line 1945 may be formed at a position biased to the right on the third string 1940.

As described above, the 3D flash memory 1900 according to another embodiment has a structure (a structure in which each of the plurality of bit lines 1920, 1930, and 1940 is connected to a relevant string through a relevant plug line) in which the plurality of bit lines 1920, 1930, and 1940 are directly connected to the plurality of strings 1920, 1930, and 1940 through the plurality of plug lines 1925, 1935, and 1945, without passing through a component other than the plurality of plug lines 1925, 1935, and 1945. Accordingly, a strapping line is not included, which differs from a conventional structure, to reduce manufacturing costs for a line.

In addition, the 3D flash memory 1900 according to another embodiment may further include contact metal pads 1926, 1936, and 1946 formed on the plurality of strings 1920, 1930, and 1940 to reduce contact resistance with the plurality of plug lines 1925, 1935, and 1945. For example, each of the contact metal pads 1926, 1936, and 1946 may be formed of metal materials on the entire region of upper portions of the plurality of strings 1920, 1930, and 1940 (in more detail, the contact metal pads 1926, 1936, and 1946 are formed on the drain doping formed on the plurality of strings 1920, 1930, and 1940). In this case, the metal material forming the contact metal pads 1926, 1936, and 1946 may be the same material as a conductive material (cobalt (Co), silicide, molybdenum (Mo), cerium (Ce), tungsten (W), titanium (Ti), tantalium (Ta), copper (Cu), or gold (Au)) constituting the plurality of plug lines 1925, 1935, and 1945.

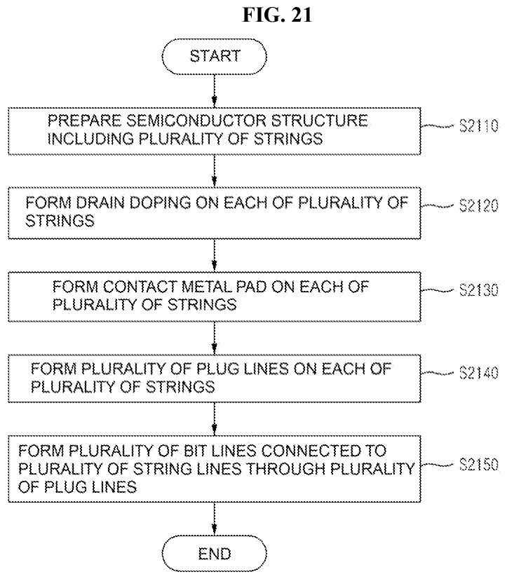

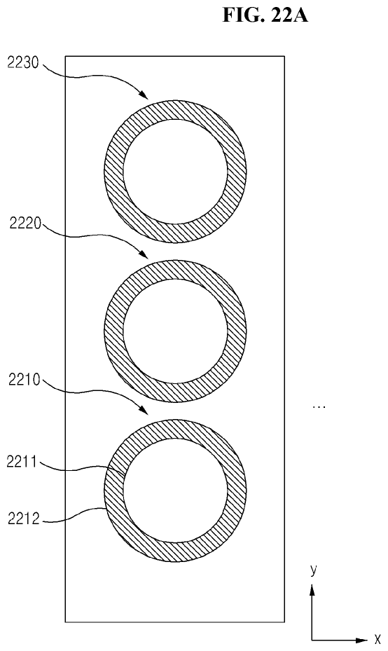

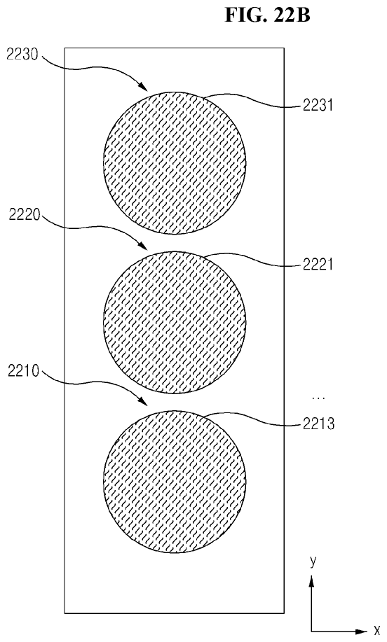

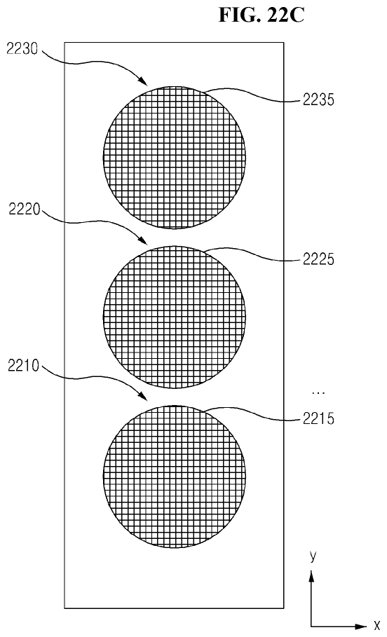

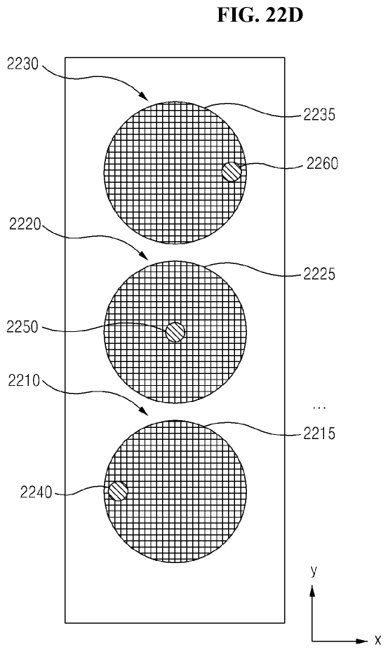

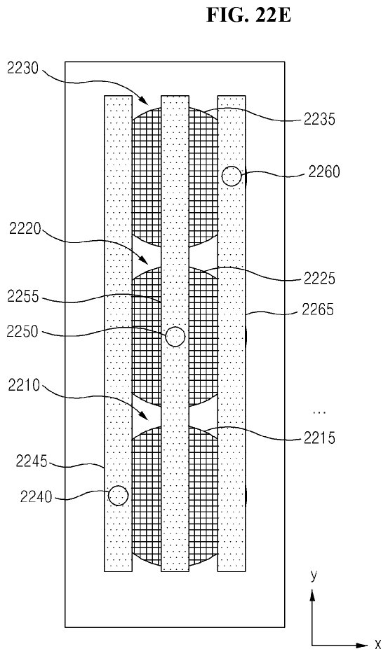

FIG. 21 is a flowchart illustrating a method for manufacturing a 3D flash memory according to another embodiment, and FIGS. 22A to 22E are a x-z cross-sectional views illustrating a method for manufacturing a 3D flash memory according to another embodiment.

On the assumption the method for manufacturing the 3D flash memory described with reference to FIGS. 21 to 22E is assumed to be performed by an automated and mechanized manufacturing system, the method may refer to the method for manufacturing the 3D flash memory 1900 described above with reference to FIG. 19.

First, the manufacturing system may prepare a semiconductor structure including a plurality of strings 2210, 2220, and 2230 extending in one direction on the substrate as illustrated in FIG. 22A, in step S2110. Hereinafter, although the drawing illustrates that the semiconductor structure includes only the plurality of strings 2210, 2220, and 2230 in brief, the semiconductor structure may further include a plurality of word lines (not illustrated) and a plurality of insulating layers (not illustrated) connected to the at least one string 2210 in the vertical direction.

In this case, the plurality of strings 2210, 2220, and 2230 are strings disposed in the same column or the same row. Each of the plurality of strings 1920, 1930, and 1940 may include a channel layer 2211 extending in one direction (e.g., the z direction) and a charge storage layer 2212 formed to surround the channel layer 2211.

Subsequently, in step S2120, the manufacturing system may form drain doping (N+ doping) 2213, 2221, and 2231 on the plurality of strings 2210, 2220, and 2230 as illustrated in FIG. 22B, in step S2120.

The manufacturing system may integrate step S2110 of preparing the semiconductor structure and step S2120 of forming the drain dopings 2213, 2221, and 2231 into one step S2110, which is similar to preparing a semiconductor structure having the doping 2213, 2221, and 2231 formed on the plurality of strings 2210, 2220, and 2230, instead of performing step S2110 of preparing the semiconductor structure, separately from step S2120 of forming the drain doping 2213, 2221, and 2231.

Next, in step S2130, the manufacturing system may form the contact metal pads 2215, 2225, and 2235 on the plurality of strings 2210, 2220, and 2230 included in the semiconductor structure as illustrated in FIG. 22C. In this case, the contact metal pads 2215, 2225, and 2235 may be formed of a metal material on the entire region of the upper portions of the plurality of strings 2210, 2220, and 2230 to reduce contact resistance with the plurality of plug lines 2240, 2250, and 2260 to be formed in step S2140 to be described later. For example, the contact metal pads 2215, 2225, and 2235 may be formed of a metal material including at least one of cobalt (Co), silicide, molybdenum (Mo), cerium (Ce), tungsten (W), titanium (Ti), tantalium (Ta), copper (Cu), or gold (Au). A process of forming the contact metal pads 2215, 2225, and 2235 may include various processes such as a Silicidation process or a chemical mechanical polishing (CMP) process in detail.

Similarly, the manufacturing system may integrate step S2130 of forming the contact metal pads 2215, 2225, and 2235, and step S2110 of preparing the semiconductor structure 1310 into one step S2110, which is similar to preparing a semiconductor structure having the contact metal pads 2215, 2225, and 2235 formed on the plurality of strings 2210, 2220, and 2230, instead of performing step of forming the contact metal pads 2215, 2225, and 2235, separately from step S2110 of preparing the semiconductor structure 1310 In this case, the manufacturing system may prepare the semiconductor structure including the plurality of strings 2210, 2220, and 2230 formed thereon with the contact metal pads 2215, 2225, and 2235 (in more detail, the contact metal pads 2215, 2225, and 2235 are formed on the drain dopings 2213, 2221, and 2231 of the plurality of strings 2210, 2220, and 2230) in step S2110.

Next, in step S2140, the manufacturing system may form the contact metal pads 2240, 2250, and 2260 on the plurality of strings 2210, 2220, and 2230 included in the semiconductor structure as illustrated in FIG. 22D. In more detail, the manufacturing system may form a plurality of plug lines 2240, 2250, and 2260 such that the plurality of bit lines 2245, 2255, and 2265 to be formed in step S2150 to be described later is directly connected to the plurality of strings 2210, 2220, and 2230 through only the plurality of plug lines 2240, 2250, and 2260 without passing through components other than the plurality of plug lines 2240, 2250, and 2260. For example, the manufacturing system may form the plurality of plug lines 2210, 2220, and 2230 by using a conductive material cobalt (Co), silicide, molybdenum (Mo), cerium (Ce), tungsten (W), titanium (Ti), tantalium (Ta), copper (Cu), or gold (Au) to have a fine thickness (e.g., in the range of 10 nm to 50 nm) based on the cross-section diameters of the plurality of strings 2210, 2220, and 2230, while extending the plug lines 2240, 2250, and 2260 in one direction (for example, the z direction) to be connected to upper portions of the plurality of strings 2210, 2220, and 2230. To this end, the plurality of plug lines 2240, 2250, and 2260 may be formed on the plurality of strings 2210, 2220, and 2230 through an extreme ultraviolet (EUV) process, which is a lithographic process using extremely ultraviolet (ultraviolet). For example, when each of the plurality of strings 2210, 2220, and 2230 has a cross-sectional diameter of 120 nm and three strings are provided in one row as illustrated in the drawing, each of the plurality of plug lines 2240, 2250, and 2260 may be formed to have a fine thickness of 20 nm.

In this case, in step S2140, when forming the plurality of plug lines 2240, 2250, and 2260, the manufacturing system may consider the relative positions of the plurality of plug lines 2240, 2250, and 2260 on the plurality of strings 2210, 2220, and 2230. In other words, positions for forming the plurality of plug lines 2240, 2250, and 2260 on the plurality of strings 2210, 2220, and 2230 may be determined complementarily from each other. In detail, in step S2140, the manufacturing system may determine the positions of the plurality of plug lines 2240, 2250, and 2260 such that the plurality of plug lines 2240, 2250, and 2260 are offset from each other on the plurality of plug lines 2240, 2250, and 2260, and may form the plurality of plug lines 2240, 2250, and 2260 depending on the determined positions. In detail, in step S2140, the manufacturing system may form the plurality of plug lines 2240, 2250, and 2260 such that positions of the plurality of plug lines 2240, 2250, and 2260 on the plurality of strings 2210, 2220, and 2230 are offset from each other

For example, the manufacturing system may individually form the plurality of plurality of plug lines 2240, 2250, and 2260 such that the plurality of plug lines 2240, 2250, and 2260 are positioned at mutually different positions of the plurality of strings 2210, 2220, and 2230. For example, the first plug line 2240 may be formed at a position biased to the left on the first string 2210, the second plug line 2250 may be formed at the center on the second string 2220, and the third plug line 2260 may be formed at a position biased to the right on the third string 2230.

Thereafter, the manufacturing system may form the plurality of bit lines 2245, 2255, and 2265 connected to the plurality of strings 2210, 2220, and 2230 through the plurality of plug lines 2240, 2250, and 2260, as illustrated in FIG. 22E, in step S2150.

While embodiments have been shown and described with reference to the accompanying drawings, it will be apparent to those skilled in the art that various modifications and variations can be made from the foregoing descriptions. For example, adequate effects may be achieved even if the foregoing processes and methods are carried out in different order than described above, and/or the aforementioned elements, such as systems, structures, devices, or circuits, are combined or coupled in different forms and modes than as described above or be substituted or switched with other components or equivalents.

Therefore, other implements, other embodiments, and equivalents to claims are within the scope of the following claims.

1. A 3D flash memory comprising:
a substrate;
at least one string extending in one direction on the substrate; and
at least two intermediate lines disposed at an intermediate point in the direction in which the at least one string extends, wherein each of the at least two intermediate lines are fixedly used as a source electrode or a drain electrode for the at least one string.

2. The 3D flash memory of claim 1, wherein the at least two intermediate lines includes:
at least one intermediate source line used as a source electrode for the at least one string; and
at least one intermediate drain line used as a drain electrode for the at least one string.

3. The 3D flash memory of claim 2, wherein each of the at least one intermediate source line and the at least one intermediate drain line are provided to be separated from each other in a single layer.

4. The 3D flash memory of claim 2, wherein each of the at least one intermediate source line and the at least one intermediate drain line are provided in mutually different layers.

5. The 3D flash memory of claim 2, wherein the at least one intermediate source line and the at least one intermediate drain line are connected to mutually different strings, respectively, of at least one upper string and at least one lower string which are obtained by dividing the at least one string into two parts by the at least one intermediate source line and the at least one intermediate drain line.

6. A 3D flash memory comprising:
a string extending in one direction on a substrate, wherein the string includes a channel layer extending in the one direction and a charge storage layer extending in the one direction while surrounding the channel layer;
at least one selection line connected to an upper end or a lower end of the string in a vertical direction; and
a plurality of word lines positioned at an upper portion or a lower portion of the at least one selection line and connected to the string in the vertical direction,
wherein the channel layer includes:
a first region corresponding to the plurality of word lines and a second region corresponding to the at least one selection line, and
wherein the first region and the second region include mutually different materials.

7. The 3D flash memory of claim 6, wherein the first region includes single crystalline silicon or polysilicon, and
wherein the second region includes an oxide semiconductor material.

8. The 3D flash memory of claim 6, wherein the second region is used to:
block a leakage current for the at least one selection line; and
improve a characteristic of a transistor of the at least one selection line.

9. The 3D flash memory of claim 6, wherein the second region further includes:
an N-type junction formed on a contact interface with the first region.

10. The 3D flash memory of claim 9, wherein the N-type junction is used to:
reduce a contact resistance between the first region and the second region.

11. The 3D flash memory of claim 9, wherein the at least one selection line is adjacent to one of the upper end or the lower end of the string in the vertical direction and includes a plurality of selection lines, and
wherein the second region is used to:
block a leakage current for an upper selection line of two selection lines, improve a characteristic of a transistor of the at least one selection line, and inject a hole into the first region through the N-type junction in relation to a lower selection line of the two selection lines.

12. A 3D flash memory comprising:
a substrate;
at least one string extending in one direction on the substrate;
at least one plug line formed on the at least one string; and
at least one bit line connected to the at least one string through the at least one plug line,
wherein the at least one bit line is directly connected to the at least one string through only the at least one plug line without passing through a component other than the at least one plug line.

13. The 3D flash memory of claim 12, wherein a contact metal pad is formed on the at least one string.

14. The 3D flash memory of claim 13, wherein the contact metal pad includes a metal material applied on an entire region of an upper portion of the at least one string to reduce a contact resistance with the at least one plug line.

15. The 3D flash memory of claim 12, wherein a position for forming the at least one plug line on the at least one string is determined based on a position in which at least one different plug line on at least one different string positioned in the same column or the same row as a position of the at least one string is formed on the at least one different string.
